(19) United States
(12) Patent Application Publication
(10) Pub. No.: US 2025/0035829 A1
(43) Pub. Date: Jan. 30, 2025

(54) COATED TEXTURED GLASS ARTICLES AND METHODS OF MAKING SAME

(71) Applicant: CORNING INCORPORATED, CORNING, NY (US)

(72) Inventors: Jaymin Amin, CORNING, NY (US); Xinyu Cao, Shanghai (CN); Ling Chen, Shanghai (CN); Wanghui Chen, Zhejiang (CN); Jiangwei Feng, Newtown, PA (US); Robert Randall Hancock, Jr., CORNING, NY (US); Shandon Dee Hart, Elmira, NY (US); Yuhui Jin, Painted Post, NY (US); Karl William Koch, III, Elmira, NY (US); Carlo Anthony Kosik Williams, Painted Post, NY (US); Aize Li, Painted Post, NY (US); Lin Lin, Painted Post, NY (US); Loretta Jane Moses, CORNING, NY (US); Meng Shang, Painted Post, NY (US); Nicholas Michael Walker, Painted Post, NY (US)

(21) Appl. No.: 18/841,420

(22) PCT Filed: Feb. 20, 2023
(86) PCT No.: PCT/US2023/013406

§ 371 Date: Aug. 26, 2024

(30) Foreign Application Priority Data
Feb. 28, 2022 (CN) 202210191806.8

(51) Int. Cl. G02B 5/28

(52) U.S. Cl. CPC G02B 5/28

(57) ABSTRACT

A coated textured glass article is described herein that comprises: a glass body comprising a first surface; a plurality of polyhedral surface features extending from the first surface; and a coating disposed on the first surface of the body and the plurality of polyhedral surface features. Each of the plurality of polyhedral surface features comprises a base on the first surface and a plurality of facets extending from the base and converging toward one another. The coating comprises a multilayer interference stack.

### CLAIM OF PRIORITY

This application claims the benefit of priority of Chinese Patent Application Serial No.: 202210191806.8, filed on Feb. 28, 2022, the content of which is relied upon and incorporated herein by reference in its entirety.

### FIELD

The present specification generally relates to textured glass articles and, in particular, to coated textured glass articles having enhanced reflectance and hardness and tunable color properties.

### TECHNICAL BACKGROUND

Aluminosilicate glass articles may exhibit superior ion-exchangeability and drop performance. Various industries, including the consumer electronics industry, desire textured, reflective materials with the same or similar strength and fracture toughness properties. However, conventional texturing processes may not produce the desired appearance on certain aluminosilicate glass articles.

Accordingly, a need exists for an alternative method to produce aluminosilicate glass articles having enhanced reflectance and tunable color properties while maintaining or improving the hardness of the article.

### SUMMARY

According to a first aspect A1, a coated textured glass article may comprise: a glass body comprising a first surface; a glass body comprising a first surface; a plurality of polyhedral surface features extending from the first surface, each of the plurality of polyhedral surface features comprising a base on the first surface and a plurality of facets extending from the base and converging toward one another; and a coating disposed on the first surface of the body and the plurality of polyhedral surface features, the coating comprising a multilayer interference stack.

A second aspect A2 includes the article according to the first aspect A1, wherein the plurality of polyhedral surface features comprises a surface feature size greater than or equal to 50 μm and less than or equal to 300 μm.

A third aspect A3 includes the article according to the first aspect A1 or the second aspect A2, wherein the plurality of polyhedral surface features comprises a surface feature height greater than or equal to 10 μm and less than or equal to 40 μm.

A fourth aspect A4 includes the article according to any one of the first aspect A1 to the third aspect A3, wherein the plurality of polyhedral surface features comprises triangular pyramids, quadrangular pyramids, or a combination thereof.

A fifth aspect A5 includes the article according to any one of the first aspect A1 to the fourth aspect A4, wherein the plurality of polyhedral surface features comprises a facet angle greater than or equal to 100 and less than or equal to 25°.

A sixth aspect A6 includes the article according to any one of the first aspect A1 to the fifth aspect A5, wherein the plurality of polyhedral surface features comprises a surface roughness greater than or equal to 2 μm and less than or equal to 7 μm.

A seventh aspect A7 includes the article according to any one of the first aspect A1 to the sixth aspect A6, wherein the multilayer interference stack comprises a plurality of layers, wherein the plurality of layers comprises at least one low refractive index layer and at least one high refractive index layer.

An eighth aspect A8 includes the article according to the seventh aspect A7, wherein the multilayer interference stack comprises at least one period, each period comprising one of the at least one low refractive index layers and one of the at least one high refractive index layers.

A ninth aspect A9 includes the article according to the eighth aspect A8, wherein the multilayer interference stack comprises from 1 to 20 periods.

A tenth aspect A10 includes the article according to any one of the seventh aspect A7 to the ninth aspect A9, wherein the at least one low refractive index layer comprises SiO₂, Al₂O₃, GeO₂, SiO, AlOₓN_{y}, SiOₓNᵤ, SiAlₓO_{y}, SiᵤAlᵥOₓN_{y}, MgO, MgAl₂O₄, MgF₂, BaF₂, CaF₂, DyF₃, YbF₃, CeF₃, or a combination thereof, wherein subscripts “u,” “x,” and “y” are from 0 to 1.

An eleventh aspect A11 includes the article according to any one of the seventh aspect A7 to the tenth aspect A10, wherein the at least one high refractive index layer comprises SiᵤAlᵥOₓN_{y}, Ya₂O₅, Nb₂O₅, AlN, Si₃N₄, AlOₓN_{y}, SiOₓN_{y}, HfO₂, TiO₂, ZrO₂, Y₂O₃, Al₂O₃, MoO₃, diamond-like carbon, or a combination thereof, wherein subscripts “u,” “x,” and “y” are from 0 to 1.

A twelfth aspect A12 includes the article according to any one of the seventh aspect A7 to the eleventh aspect A11, wherein the at least one low refractive index layer comprises a thickness greater than or equal to 2 nm and less than or equal to 200 nm.

A thirteenth aspect A13 includes the article according to any one of the seventh aspect A7 to the twelfth aspect A12, wherein the at least one high refractive index layer comprises a thickness greater than or equal to 5 nm and less than or equal to 5000 nm.

A fourteenth aspect A14 includes the article according to any one of the first aspect A1 to the thirteenth aspect A13, wherein the multilayer interference stack comprises an outer surface opposite the first surface of the body, and wherein the article comprises a hardness greater than or equal to 10 GPa, as measured at the outer surface by a Berkovich Indenter Hardness Test along an indentation depth of 100 nm to 500 nm.

A fifteenth aspect A15 includes the article according to any one of the first aspect A1 to the fourteenth aspect A14, wherein the multilayer interference stack comprises an outer surface opposite the first surface of the body, and wherein the article comprises a single side average photopic light reflectance greater than or equal to 4%, as measured at the outer surface at an incident illumination angle of 6°, referenced to normal incidence, over a wavelength range from 400 nm to 700 nm.

A sixteenth aspect A16 includes the article according to the fifteenth aspect A15, wherein the single side average photopic light reflectance of the article is greater than or equal to 7%, as measured at the outer surface at an incident illumination angle of 6°, referenced to normal incidence, over a wavelength range from 400 nm to 700 nm.

A seventeenth aspect A17 includes the article according to the sixteenth aspect A16, wherein the single side average photopic light reflectance of the article is greater than or equal to 10%, as measured at the outer surface at an incident illumination angle of 6°, referenced to normal incidence, over a wavelength range from 400 nm to 700 nm.

An eighteenth aspect A18 includes the article according to the seventh aspect A17, wherein the single side average photopic light reflectance of the article is greater than or equal to 20%, as measured at the outer surface at an incident illumination angle of 6°, referenced to normal incidence, over a wavelength range from 400 nm to 700 nm.

A nineteenth aspect A19 includes the article according to any one of the first aspect A1 to the eighteenth aspect A18, wherein the multilayer interference stack comprises an outer surface opposite the first surface of the body, and wherein the article comprises a peak single side light reflectance greater than or equal to 25%, as measured at the outer surface at an incident illumination angle of 6°, referenced to normal incidence, over a wavelength range from 400 nm to 700 nm.

A twentieth aspect A20 includes the article according to the nineteenth aspect A19, wherein the peak single side light reflectance of the article is greater than or equal to 40%, as measured at the outer surface at an incident illumination angle of 6°, referenced to normal incidence, over a wavelength range from 400 nm to 700 nm.

A twenty-first aspect A21 includes the article according to the twentieth aspect A20, wherein the peak single side light reflectance of the article is greater than or equal to 50%, as measured at the outer surface at an incident illumination angle of 6°, referenced to normal incidence, over a wavelength range from 400 nm to 700 nm.

A twenty-second aspect A22 includes the article according to any one of the first aspect A1 to the twenty-first aspect A21, wherein the article comprises a peak single side light reflectance from 520 nm to 560 nm, as measured at the outer surface a tan incident illumination angle of 6°, referenced to normal incidence, over a wavelength range from 400 nm to 700 nm.

A twenty-third aspect A23 includes the article according to any one of the first aspect A1 to the twenty-second aspect A22, wherein the article comprises an article reflectance color coordinate L* greater than or equal to 20 and less than or equal to 90, as measured under D65 illumination and a 100 standard observer angle.

A twenty-fourth aspect A24 includes the article according to any one of the first aspect A1 to the twenty-third aspect A23, wherein the article comprises at least one of article reflectance color coordinates a* and b* greater than or equal to −30 and less than or equal to 30, as measured under D65 illumination and a 100 standard observer angle.

A twenty-fifth aspect A25 includes the article according to any one of the first aspect A1 to the twenty-fourth aspect A24, wherein: the article exhibits an angular color shift greater than or equal to 5, as measured at an incident illumination angle greater than or equal to 20 degrees, referenced to normal incidence, under D65 illumination; and the angular color shift is calculated using the equation √((a*₂−a*₁)²+(b*₂−b*₁)²), with a*₁, and b*₁ representing the coordinates of the article when viewed at normal incidence and a*₂, and b*₂ representing the coordinates of the article when viewed at the incident illumination angle.

A twenty-sixth aspect A26 includes the article according to any one of the first aspect A1 to the twenty-fifth aspect A25, wherein the article exhibits a reference point color shift greater than or equal to 2, as measured at a normal incidence under D65 illumination; and the reference point color shift is calculated using the equation √(a*²+b*²).

A twenty-seventh aspect A27 includes the article according to any one of the first aspect A1 to the twenty-sixth aspect A26, wherein the glass body comprises aluminosilicate glass.

A twenty-eighth aspect A28 includes the article according to any one of the first aspect A1 to the twenty-seventh aspect A27, wherein the glass body comprises a glass-ceramic body.

According to a twenty-ninth aspect A29, a coated textured glass article may comprise: a glass body comprising a first surface; a plurality of polyhedral surface features extending from the first surface; and a coating disposed on the first surface of the body and the plurality of polyhedral surface features, the coating comprising a multilayer interference stack, the multilayer interference stack comprising an outer surface opposite the first surface of the body, wherein: the article comprises a single side average photopic light reflectance greater than or equal to 4%, as measured at the outer surface at an incident illumination angle of 6°, referenced to normal incidence, over a wavelength range from 400 nm to 700 nm.

A thirtieth aspect A30 includes the article according to the twenty-ninth aspect A29, wherein the article comprises a hardness greater than or equal to 10 GPa, as measured on the outer surface by a Berkovich Indenter Hardness Test along an indentation depth of 100 nm to 500 nm.

A thirty-first aspect A31 includes the article according to the twenty-ninth aspect A29 or the thirtieth aspect A30, wherein the single side average photopic light reflectance of the article is greater than or equal to 7%, as measured at the outer surface at an incident illumination angle of 6°, referenced to normal incidence, over a wavelength range from 400 nm to 700 nm.

A thirty-second aspect A32 includes the article according to the thirty-first aspect A31, wherein the single side average photopic light reflectance of the article is greater than or equal to 10%, as measured at the outer surface at an incident illumination angle of 6°, referenced to normal incidence, over a wavelength range from 400 nm to 700 nm.

A thirty-third aspect A33 includes the article according to the thirty-second aspect A32, wherein the single side average photopic light reflectance of the article is greater than or equal to 20%, as measured at the outer surface at an incident illumination angle of 6°, referenced to normal incidence, over a wavelength range from 400 nm to 700 nm.

A thirty-fourth aspect A34 includes the article according to any one of the twenty-ninth aspect A29 to the thirty-third A33 aspect, wherein the article comprises a peak single side light reflectance greater than or equal to 25%, as measured at the outer surface at an incident illumination angle of 6°, referenced to normal incidence, over a wavelength range from 400 nm to 700 nm.

A thirty-fifth aspect A35 includes the article according to the thirty-fourth aspect A34, wherein the peak single side light reflectance of the article is greater than or equal to 40%, as measured at the outer surface at an incident illumination angle of 6°, referenced to normal incidence, over a wavelength range from 400 nm to 700 nm.

A thirty-sixth aspect A36 includes the article according to the thirty-fifth aspect A35, wherein the peak single side light reflectance of the article is greater than or equal to 50%, as measured at the outer surface at an incident illumination angle of 6°, referenced to normal incidence, over a wavelength range from 400 nm to 700 nm.

A thirty-seventh aspect A37 includes the article according to any one of the twenty-ninth aspect A29 to the thirty-sixth aspect A36, wherein the article comprises a peak single side light reflectance from 520 nm to 560 nm, as measured at the outer surface at an incident illumination angle of 6°, referenced to normal incidence, over a wavelength range from 400 nm to 700 nm.

A thirty-eighth aspect A38 includes the article according to any one of the twenty-ninth aspect A29 to the thirty-seventh aspect A37, wherein the article comprises an article reflectance color coordinate L* greater than or equal to 20 and less than or equal to 90, as measured under D65 illumination and a 100 standard observer angle.

A thirty-ninth aspect A39 includes the article according to any one of the twenty-ninth aspect A29 to the thirty-eighth aspect A38, wherein the article comprises at least one of article reflectance color coordinates a* and b* greater than or equal to −30 and less than or equal to 30, as measured under D65 illumination and a 10° standard observer angle.

A fortieth aspect A40 includes the article according to any one of the twenty-ninth aspect A29 to the thirty-ninth aspect A39, wherein: the article exhibits an angular color shift greater than or equal to 5, as measured at an incident illumination angle greater than or equal to 20 degrees, referenced to normal incidence, under D65 illumination; and the angular color shift is calculated using the equation ((a*₂−a*₁)²+(b*₂−b*₁)²), with a*₁, and b*₁ representing the coordinates of the article when viewed at normal incidence and a*₂, and b*₂ representing the coordinates of the article when viewed at the incident illumination angle.

A forty-first aspect A41 includes the article according to any one of the twenty-ninth aspect A29 to the fortieth aspect A40, wherein the article exhibits a reference point color shift greater than or equal to 2, as measured at a normal incidence under D65 illumination; and the reference point color shift is calculated using the equation (a*²+b*²).

A forty-fourth aspect A44 includes the article according to any one of the twenty-ninth aspect A29 to the forty-third aspect A43, wherein the plurality of polyhedral surface features comprises triangular pyramids, quadrangular pyramids, or a combination thereof.

A forty-fifth aspect A45 includes the article according to any one of the twenty-ninth aspect A29 to the forty-fourth aspect A44, wherein the multilayer interference stack comprises a plurality of layers, wherein the plurality of layers comprises at least one low refractive index layer and at least one high refractive index layer.

A forty-sixth aspect A46 includes the article according to the forty-fifth aspect A45, wherein the at least one low refractive index layer comprises SiO₂ and the at least one high refractive index layer comprise Si₃N₄.

A forty-seventh aspect A47 includes the article according to any one of the forty-fifth aspect A45 or the forty-sixth aspect A46, wherein: the at least one low refractive index layer comprises a thickness greater than or equal to 2 nm and less than or equal to 200 nm; and the at least on high refractive index layer comprises a thickness greater than or equal to 5 nm and less than or equal to 5000 nm.

A forty-eighth aspect A48 includes the article according to any one of the twenty-ninth aspect A29 to the forty-seventh aspect A47, wherein the glass body comprises aluminosilicate glass.

A forty-ninth aspect A49 includes the article according to any one of the twenty-ninth aspect A29 to the forty-eighth aspect A48, wherein the glass body comprises a glass-ceramic body.

According to a fiftieth aspect A50, a coated textured glass article may comprise: a glass body comprising a first surface; a plurality of polyhedral surface features extending from the first surface, each of the plurality of polyhedral surface features comprising a base on the first surface and a plurality of facets extending from the base and converging toward one another, the plurality of polyhedral surface features comprising a surface feature size greater than or equal to 50 μm and less than or equal to 300 μm and a surface feature height greater than or equal to 10 μm and less than or equal to 40 μm; and a coating disposed on the first surface of the body and the plurality of polyhedral surface features, the coating comprising a multilayer interference stack, the multilayer interference stack comprising an outer surface opposite the first surface of the body, wherein: the article comprises a single side average photopic light reflectance greater than or equal to 4%, as measured at the outer surface at an incident illumination angle of 6°, referenced to normal incidence, over a wavelength range from 400 nm to 700 nm.

A fifty-first aspect A51 includes the article according to the fiftieth aspect A50, wherein the plurality of polyhedral surface features comprises a facet angle greater than or equal to 100 and less than or equal to 25° and a surface roughness greater than or equal to 2 μm and less than or equal to 7 μm.

A fifty-second aspect A52 includes the article according to the fiftieth aspect A50 or the fifty-first aspect A51, wherein the plurality of polyhedral surface features comprises triangular pyramids, quadrangular pyramids, or a combination thereof.

A fifty-third aspect A53 includes the article according to any one of the fiftieth aspect A50 to the fifty-second aspect A52, wherein the multilayer interference stack comprises a plurality of layers, the plurality of layers comprising at least one low refractive index layer and at least one high refractive index layer.

A fifty-fourth aspect A54 includes the article according to the fifty-third aspect A53, wherein the at least one low refractive index layer comprises SiO₂ and the at least one high refractive index layer comprises Si₃N₄.

A fifty-fifth aspect A55 includes the article according to the fifty-third aspect A53 or the fifty-fourth aspect A54, wherein the at least one low refractive index layer comprises a thickness greater than or equal to 2 nm and less than or equal to 200 nm and the at least one high refractive index layer comprises a thickness greater than or equal to 5 nm and less than or equal to 5000 nm.

A fifty-sixth aspect A56 includes the article according to any one of the fiftieth aspect A50 to the fifty-fifth aspect A55, wherein the article comprises a hardness greater than or equal to 10 GPa, as measured on the outer surface by a Berkovich Indenter Hardness Test along an indentation depth of 100 nm to 500 nm.

A fifty-seventh aspect A57 includes the article according to any one of the fiftieth aspect A50 to the fifty-sixth aspect A56, wherein the single side average photopic light reflectance of the article is greater than or equal to 7%, as measured at the outer surface at an incident illumination angle of 6°, referenced to normal incidence, over a wavelength range from 400 nm to 700 nm.

A fifty-eighth aspect A58 includes the article according to the fifty-seventh aspect A57, wherein the single side average photopic light reflectance of the article at the outer surface is greater than or equal to 10%, as measured at the outer surface at an incident illumination angle of 6°, referenced to normal incidence, over a wavelength range from 400 nm to 700 nm.

A fifty-ninth aspect A59 includes the article according to the fifty-eighth aspect A58, wherein the single side average photopic light reflectance of the article is greater than or equal to 20%, as measured at the outer surface at an incident illumination angle of 6°, referenced to normal incidence, over a wavelength range from 400 nm to 700 nm.

A sixtieth aspect A60 includes the article according to any one of the fiftieth aspect A50 to the fifty-ninth aspect A59, wherein the article comprises a peak single side light reflectance greater than or equal to 25%, as measured at the outer surface at an incident illumination angle of 6°, referenced to normal incidence, over a wavelength range from 400 nm to 700 nm.

A sixty-first aspect A61 includes the article according to the sixtieth aspect A60, wherein the peak single side light reflectance of the article is greater than or equal to 40%, as measured at the outer surface at an incident illumination angle of 6°, referenced to normal incidence, over a wavelength range from 400 nm to 700 nm.

A sixty-second aspect A62 includes the article according to the sixty-first aspect A61, wherein the peak single side light reflectance of the article is greater than or equal to 50%, as measured at the outer surface at an incident illumination angle of 6°, referenced to normal incidence, over a wavelength range from 400 nm to 700 nm.

A sixty-third aspect A63 includes the article according to any one of the fiftieth aspect A50 to the sixty-second aspect A62, wherein the article wherein the article comprises a peak single side light reflectance from 520 nm to 560 nm, as measured at the outer surface at an incident illumination angle of 6°, referenced to normal incidence, over a wavelength range from 400 nm to 700 nm.

A sixty-fourth aspect A64 includes the article according to any one of the fiftieth aspect A50 to the sixty-third aspect A63, wherein the article comprises an article reflectance color coordinate L* greater than or equal to 20 and less than or equal to 90, as measured under D65 illumination and a 100 standard observer angle.

A sixty-fifth aspect A65 includes the article according to any one of the fiftieth aspect A50 to the sixty-fourth aspect A64, wherein the article comprises at least one of article reflectance color coordinates a* and b* greater than or equal to −30 and less than or equal to 30, as measured under D65 illumination and a 100 standard observer angle.

A sixty-sixth aspect A66 includes the article according to any one of the fiftieth aspect A50 to the sixty-fifth aspect A65, wherein: the article exhibits an angular color shift greater than or equal to 5, as measured at an incident illumination angle greater than or equal to 20 degrees, referenced to normal incidence, under D65 illumination; and the angular color shift is calculated using the equation ((a*₂−a*₁)²+(b*₂−b*₁)²), with a*₁, and b*₁ representing the coordinates of the article when viewed at normal incidence and a*₂, and b*₂ representing the coordinates of the article when viewed at the incident illumination angle.

A sixty-seventh aspect A67 includes the article according to any one of the fiftieth aspect A50 to the sixty-sixth aspect A66, wherein the article exhibits a reference point color shift greater than or equal to 2, as measured at a normal incidence under D65 illumination; and the reference point color shift is calculated using the equation (a*²+b*²).

According to a sixty-eighth aspect A68, a consumer electronic device may comprise: a housing having a front surface, a back surface, and side surfaces; and electrical components provided at least partially within the housing, the electrical components including at least a controller, a memory, and a display, the display being provided at or adjacent the front surface of the housing; wherein the back surface of the housing includes the coated textured glass article according to any one of the first aspect A1 to the twenty-eighth aspect A28.

According to a sixty-ninth aspect A69, a consumer electronic device may comprise: a housing having a front surface, a back surface, and side surfaces; and electrical components provided at least partially within the housing, the electrical components including at least a controller, a memory, and a display, the display being provided at or adjacent the front surface of the housing; wherein the back surface of the housing includes the coated textured glass article according to any one of the twenty-ninth aspect A29 to the forty-ninth aspect A40.

According to a seventieth aspect A70, a consumer electronic device may comprise: a housing having a front surface, a back surface, and side surfaces; and electrical components provided at least partially within the housing, the electrical components including at least a controller, a memory, and a display, the display being provided at or adjacent the front surface of the housing; wherein the back surface of the housing includes the coated textured glass article according to any one of the fiftieth aspect A50 to the sixty-seventh aspect A67.

Additional features and advantages of the coated textured glass articles described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a plan view of a conventional glass article;

FIG. 2 schematically depicts a plan view of a textured glass article without a coating thereon;

FIG. 3 schematically depicts a plan view of a coated textured glass article, according to one or more embodiments shown and described herein;

FIG. 4 schematically depicts a plan view of a textured glass article prior to disposing a coating thereon, according to one or more embodiments shown and described herein;

FIG. 5 schematically depicts a plan view of a polyhedral surface feature, according to one or more embodiments shown and described herein;

FIG. 6 schematically depicts a plan view of a polyhedral surface features, according to one or more embodiments shown and described herein;

FIG. 7 schematically depicts an etchant reacting with an aluminosilicate glass article, according to one or more embodiments shown or described herein;

FIG. 8 is a flow diagram of a method of forming a textured glass article, according to one or more embodiments shown and described herein;

FIG. 9 schematically depicts a step of the method of forming a textured glass article, according to one or more embodiments shown and described herein;

FIG. 10 schematically depicts another step of the method of forming a textured glass article, according to one or more embodiments shown and described herein;

FIG. 11 schematically depicts another step of the method of forming a textured glass article, according to one or more embodiments shown and described herein;

FIG. 12 schematically depicts a plan view of a coated textured glass article, according to one or more embodiments shown and described herein;

FIG. 13 schematically depicts a cross sectional view of a coating, according to one or more embodiments shown and described herein;

FIG. 14 is a plan view of an exemplary electronic device incorporating any of the coated textured glass articles, according to one or more embodiments shown and described herein;

FIG. 15 is a perspective view of the exemplary electronic device of FIG. 14;

FIG. 16 is a perspective view of the exemplary electronic device of FIG. 14;

FIG. 17 is an optical microscope image with a magnification of 100× of a textured glass article prior to disposing a coating thereon, according to one or more embodiments shown and described herein;

FIG. 18 is an optical microscope image with a magnification of 200× of the textured glass article shown in FIG. 17;

FIG. 19 is an optical microscope image with a magnification of 100× of a textured glass article prior to disposing a coating thereon, according to one or more embodiments shown and described herein;

FIG. 20 is an optical microscope image with a magnification of 200× of the textured glass article in FIG. 19;

FIG. 21 is an optical microscope image with a magnification of 100× of a coated textured glass article, according to one or more embodiments shown and described herein;

FIG. 22 is an optical microscope image with a magnification of 200× of the coated textured glass article shown in FIG. 21;

FIG. 23 is an optical microscope image with a magnification of 100× of a coated textured glass article, according to one or more embodiments shown and described herein;

FIG. 24 is an optical microscope image with a magnification of 200× of the coated textured glass article shown in FIG. 23;

FIG. 25 is a plot showing reflectance (y-axis; in percentage (%)) as a function of wavelength (x-axis; in nanometers (nm)) for a textured glass article and for coated textured glass articles, according to one or more embodiments shown and described herein; and

FIG. 26 is a plot showing hardness (y-axis; in gigapascals (GPa)) as a function of displacement into surface (x-axis; in nanometers (nm) for a textured glass article and a coated textured glass article, according to one or more embodiments shown and described herein.

### DETAILED DESCRIPTION

Reference will not be made in detail to various embodiments of coated textured glass articles having enhanced reflectance and hardness and tunable color properties.

According to embodiments, a coated textured glass article comprises: a glass body comprising a first surface; a plurality of polyhedral surface features extending from the first surface; and a coating disposed on the first surface of the body and the plurality of polyhedral surface features. Each of the plurality of polyhedral surface features may comprise a base on the first surface and a plurality of facets extending from the base and converging toward one another. The coating may comprise a multilayer interference stack.

According to other embodiments, a coated textured glass article comprises: a glass body comprising a first surface; a plurality of polyhedral surface features extending from the first surface; and a coating disposed on the first surface of the body and the plurality of surface features. The coating may comprise an outer surface opposite the first surface of the body. The article may comprise a single side average photopic light reflectance greater than or equal to 4%, as measured at the outer surface at an incident illumination angle of 6°, referenced to normal incidence, over a wavelength range from 400 nm to 700 nm.

According to other embodiments, a coated textured glass article comprises: a glass body comprising a first surface; a plurality of polyhedral surface features extending from the first surface; and a coating disposed on the first surface of the body and the plurality of polyhedral surface features. Each of the plurality of polyhedral surface features may comprise a base on the first surface and a plurality of facets extending from the base and converging toward one another. The plurality of polyhedral surface features may comprise a surface feature size greater than or equal to 50 μm and less than or equal to 300 μm and a surface feature height greater than or equal to 10 μm and less than or equal to 40 μm. The coating may comprise a multilayer interference stack. The article may comprise a single side average photopic light reflectance greater than or equal to 4%, as measured at the outer surface at an incident illumination angle of 6°, referenced to normal incidence, over a wavelength range from 400 nm to 700 nm.

Various embodiments of coated textured glass articles and methods of forming the same will be described herein with specific reference to the appended drawings.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

In the embodiments of the aluminosilicate glass articles described herein, the concentrations of constituent components (e.g., SiO₂, Al₂O₃, and the like) are specified in mole percent (mol %) on an oxide basis, unless otherwise specified.

Optical microscope images, as described herein, are obtained using Nikon Eclipse L200N optical microscope with 2× and 10× objectives and multiple 10× from eyepiece for a total magnification of 100× and 200×.

“Surface feature size,” as described herein, is measured using optical microscopy at 200× magnification. Images are obtained of two different 500 μm×1000 μm scanned areas. In each image, the maximum distance across the cross section of the base of the 10 largest surface features is measured. “Surface feature size” refers to the average maximum distance across the cross section of the base of the 20 surface features from the two scanned areas. For example, for surface features with a triangular base, the maximum distance across the cross section of the base is the height of the triangular base. For surface features with a rectangular base, the maximum distance across the cross section of the base is the diagonal measurement across the base.

“Surface feature height,” as described herein, refers to the average polyhedral surface feature distance between the base of the surface feature and the topmost apex of the surface feature.

“Facet angle,” as described herein, refers to the average polyhedral surface angle between a plane normal to a first surface of the aluminosilicate glass article and the facet. The facet angle is measured by arctan (height/half length) of the surface feature. “Triangular pyramid facet angle,” as used herein, refers to the average facet angle of the triangular pyramids present on the aluminosilicate glass article. “Quadrangular pyramid facet angle,” as used herein, refers to the average facet angle of the quadrangular pyramids present on the aluminosilicate glass article.

“Surface roughness,” as described herein, refers to the surface texture of a textured glass article quantified by the arithmetic average of the absolute values of the profile height deviations from the mean line, recorded within the evaluation length, as measured by a Mitutoyo SJ-310 surface roughness meter and in accordance with ISO1997. Values reported herein are reported in microns, or μm, unless otherwise expressly stated.

“Sufficient coverage,” when used herein to describe the plurality of polyhedral surface features of the textured glass article, refers to the polyhedral surface features covering greater than or equal to 90% of a major surface of the textured glass article.

“Micro-uniformity,” when used herein to describe the plurality of polyhedral surface features of the textured glass article, refers to the individual feature sizes not varying more than 20%.

“Polyhedral,” when used to describe the structure of a surface feature on a textured glass article, refers to a three-dimensional shape with flat polygonal faces and straight edges.

“Dendritic,” when used to describe the structure of a surface feature on a textured glass article, refers to a branching structure.

A thickness of a coating or layers thereof, as described herein, is measured by scanning electron microscope (SEM) of a cross-section.

“Refractive index,” as described herein, is measured using a spectroscopic ellipsometer from J. A. Woollam.

The term “hardness,” as described herein, refers to the hardness of the coated textured glass article, as measured at the outer surface of the multilayer interference stack of the coating by a Berkovich Indenter Hardness Test along an indentation depth of 100 nm to 500 nm.

The term “reflectance,” as described herein, refers to total reflectance, including specular reflectance and diffuse reflectance.

The term “single side average photopic light reflectance,” as described herein, refers to the average percentage of incident optical power that is reflected from the coated textured glass article, as measured at the outer surface of the multilayer interference stack of the coating at an incident illumination angle of 6°, referenced to normal incidence, over a wavelength range from 400 nm to 700 nm.

The term “peak single side light reflectance,” as described herein, refers to the peak percentage of incident optical power that is reflected from the coated textured glass article, as measured at the outer surface of the multilayer interference stack of the coating at an incident illumination angle of 6°, referenced to normal incidence, over a wavelength range from 400 nm to 700 nm.

The term “CIELAB color space,” as used herein, refers to a color space defined by the International Commission on Illumination (CIE) in 1976. It expresses color as three values: L* for the lightness from black (0) to white (100), a* from green (−) to red (+), and B* from blue (−) to yellow (+).

“Color properties” refers to peak single side light reflectance, reflectance color coordinates (L*, a*, and b*) in the CIELAB color space, and angular color shift.

“Neutral color,” as used herein, refers to an a* and b* value from −1.5 to 1.5.

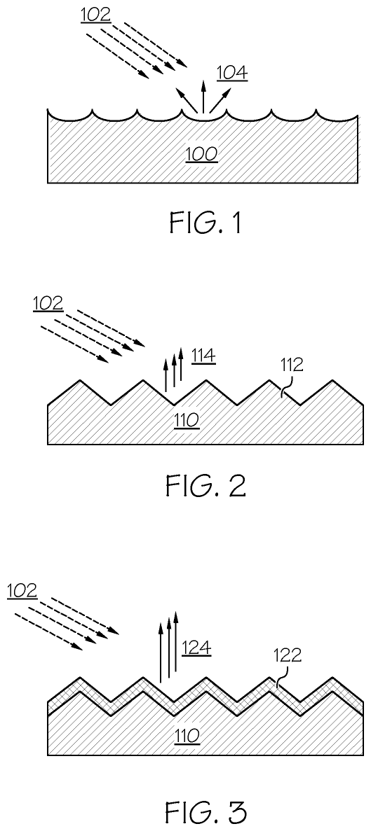

Referring now to FIG. 1, a conventional glass article with concave micro-features and a matte-finish visual appearance is shown at 100. Incident light 102 directed at the conventional glass article 100 may be reflected back in a diffuse manner as shown at 104.

Referring now to FIG. 2, to achieve a “glowing effect” (i.e., greater reflectance), etchants have been used to achieve textured glass articles as shown at 110. Properties of the textured surface, including the structure, size, coverage, and micro-uniformity of the surface features thereon may effect the appearance (e.g., reflectance or “glowing effect”) of the textured glass article 110. Due to their flat polygonal faces and straight edges, polyhedral surface features 112 may reflect incident light 102 (e.g., about 4%) back in a specular manner as shown at 114 and achieve a better “glowing effect” than a conventional glass article. While increasing the surface feature size may further enhance the “glowing effect,” the individual surface features may also become grainy. Moreover, polyhedral surface features contain sharp points, which may be easily damaged.

Disclosed herein are coated textured glass articles and methods of forming the same which mitigate the aforementioned problems such that aluminosilicate glasses may have enhanced reflectance and hardness and tunable color properties. Specifically, referring now to FIG. 3, a coating 122 disposed on the textured glass article 110 provides enhanced reflectance of incident light 102 as shown at 124 and hardness. Moreover, the coating 122 maybe modified to provide desired color properties.

### Textured Glass Article

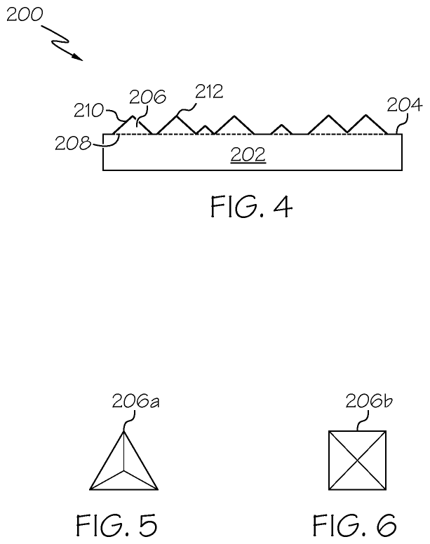

Referring now to FIG. 4, a textured glass article 200 described herein has a glass body 202 comprising a first surface 204. In embodiments, the glass body 202 may comprise an aluminosilicate glass. In embodiments, the glass body may comprise greater than or equal to 14 mol % Al₂O₃. In embodiments, the glass body 202 may comprise greater than or equal to 56 mol % and less than or equal to 72 mol % SiO₂, greater than or equal to 14 mol % and less than or equal to 25 mol % Al₂O₃, greater than or equal to 0 mol % and less than or equal to 3 mol % P₂O₅, greater than or equal to 0 mol % and less than or equal to 3 mol % ZnO, greater than or equal to 1 mol % and less than or equal to 12 mol % Li₂O, and greater than or equal to 4 mol % and less than or equal to 18 mol % Na₂O. In embodiments, the glass body 202 may comprise greater than or equal to 50 mol % and less than or equal to 66 mol % SiO₂, greater than or equal to 14 mol % and less than or equal to 25 mol % Al₂O₃, greater than or equal to 0 mol % and less than or equal to 3 mol % P₂O₅, greater than or equal to 1 mol % and less than or equal to 8 mol % B₂O₃; greater than or equal to 0 mol % and less than or equal to 3 mol % MgO, greater than or equal to 2 mol % and less than or equal to 14 mol % Li₂O, greater than or equal to 2 mol % and less than or equal to 14 mol % Na₂O, greater than or equal to 0 mol % and less than or equal to 1 mol % K₂O, and greater than or equal to 0 mol % and less than or equal to 1 mol % TiO₂. Other suitable compositions of the glass body 202 are described in U.S. Pat. No. 10,294,151B2; U.S. Pat. No. 11,104,602B2; U.S. Pat. No. 10,787,387B2; U.S. Application Publication No. 2021/0387898A1; U.S. Pat. No. 10,633,279B2; and U.S. Application Publication No. 2021/0155530A1, all of which are incorporated herein in their entireties by reference.

In one or more embodiments, the glass body 202 may be strengthened or non-strengthened. Examples of suitable glass include soda lime glass, alkali aluminosilicate glass, alkali containing borosilicate glass and alkali aluminoborosilicate glass. In some variants, the glass maybe free of Li₂O. In one or more alternative embodiments, the glass body may include crystalline such as glass ceramic substrates (which may be strengthened or non-strengthened) or may include a single crystal structure, such as sapphire. In one or more specific embodiments, the substrate includes an amorphous base (e.g., glass) and a crystalline cladding (e.g., sapphire layer, a polycrystalline alumina layer and/or or a spinel (MgAl₂O₄) layer).

The textured glass article 200 further includes a plurality of polyhedral surface features 206 extending from the first surface 204. Each of the plurality of polyhedral surface features 206 comprises a base 208 on the first surface 204, a plurality of facets 210 extending from the base 208, and at least one apex 212.

In embodiments, the facets 210 of each polyhedral surface feature 206 extend from the base 208 and converge toward one another to form the polyhedral morphology (e.g., pyramidal with 3-fold symmetry or 4-fold symmetry) of the polyhedral surface features 206. For example, as shown in FIGS. 5 and 6, in embodiments, the polyhedral surface features 206 may comprise triangular pyramids 206a, quadrangular pyramids 206b, or a combination thereof.

In embodiments, the plurality of surface features 206 may comprise a surface feature size greater than or equal to 50 μm and less than or equal to 300 μm. In embodiments, the plurality of surface features 206 may comprise a surface feature size greater than or equal to 50 μm, greater than or equal to 75 μm, or even greater than or equal to 100 μm. In embodiments, the plurality of surface features 206 may comprise a surface feature size less than or equal to 300 μm, less than or equal to 250 μm, less than or equal to 200 μm, or even less than or equal to 150 μm. In embodiments, the plurality of surface features 206 may comprise a surface feature size greater than or equal to 50 μm and less than or equal to 300 μm, greater than or equal to 50 μm and less than or equal to 250 μm, greater than or equal to 50 μm and less than or equal to 200 μm, greater than or equal to 50 μm and less than or equal to 150 μm, greater than or equal to 75 μm and less than or equal to 300 μm, greater than or equal to 75 μm and less than or equal to 250 μm, greater than or equal to 75 μm and less than or equal to 200 μm, greater than or equal to 75 μm and less than or equal to 150 μm, greater than or equal to 100 μm and less than or equal to 300 μm, greater than or equal to 100 μm and less than or equal to 250 μm, greater than or equal to 100 μm and less than or equal to 200 μm, or even greater than or equal to 100 μm and less than or equal to 150 μm, or any and all sub-ranges formed from any of these endpoints.

In embodiments, the polyhedral surface features 206 may comprise a facet angle greater than or equal to 10° and less than or equal to 25°. In embodiments, the polyhedral surface features 206 may comprise a facet angle greater than or equal to 10°, greater than or equal to 13°, or even greater than or equal to 15°. In embodiments, the polyhedral surface features 206 may comprise a facet angle less than or equal to 25°, less than or equal to 23°, less than or equal to 200 or even less than or equal to 18°. In embodiments, the polyhedral surface features 206 may comprise a facet angle greater than or equal to 10° and less than or equal to 25°, greater than or equal to 100 and less than or equal to 23°, greater than or equal to 100 and less than or equal to 20°, greater than or equal to 100 and less than or equal to 18°, greater than or equal to 13° and less than or equal to 25°, greater than or equal to 13° and less than or equal to 23°, greater than or equal to 13° and less than or equal to 20°, greater than or equal to 130 and less than or equal to 18°, greater than or equal to 150 and less than or equal to 25°, greater than or equal to 15° and less than or equal to 23°, greater than or equal to 15° and less than or equal to 20°, or even greater than or equal to 15° and less than or equal to 18°, or any and all sub-ranges formed from any of these endpoint.

In embodiments, the polyhedral surface features 206 may comprise a surface roughness greater than or equal to 2 μm and less than or equal to 7 μm. In embodiments, the polyhedral surface features 206 may comprise a surface roughness greater than or equal to 2 μm or even greater than or equal to 4 μm. In embodiments, the polyhedral surface features 206 may comprise a surface roughness less than or equal to 7 μm or even less than or equal to 6 μm. In embodiments, the polyhedral surface features 106 may comprise a surface roughness greater than or equal to 2 μm and less than or equal to 7 μm, greater than or equal to 2 μm and less than or equal to 6 μm, greater than or equal to 4 μm and less than or equal to 7 μm, or even greater than or equal to 4 μm and less than or equal to 6 μm, or any and all sub-ranges formed from any of these endpoints.

The structure and size of each polyhedral surface feature 206, along with sufficient coverage a micro-uniformity thereof, helps to achieve greater reflectance than a conventional glass article.

### Etchant

In embodiments, to achieve polyhedral surface features having sufficient coverage and micro-uniformity to produce the desired “glowing effect,” etchants to form the textured glass article may be prepared such that the etchant preferentially generates a silicon-based precipitate and minimizes the amount of aluminum based-precipitate. Silicon-based precipitates (e.g., metal fluorosilicate (MSiF₆)) lead to large, polyhedral surface features, which reflect more light than dendritic surface features. Aluminum-based precipitates (e.g., metal aluminofluoride (MAlF₅)) lead to small, dendritic surface features.

Various etchants are considered suitable to produce the textured glass articles described herein, such as those described in U.S. Provisional Patent Applciation No. 63/289,782, which is incorporated herein in its entirety by reference. For exemplary purposes, an etchant comprising ammonium bifluoride, a silicon compound, polyhydric alcohol, hydrochloric acid, and water will be described herein. However, one skilled in the art would appreciate that any etchant that preferentially generates a silicon-based precipitate and minimizes the amount of aluminum based-precipitate may be used.

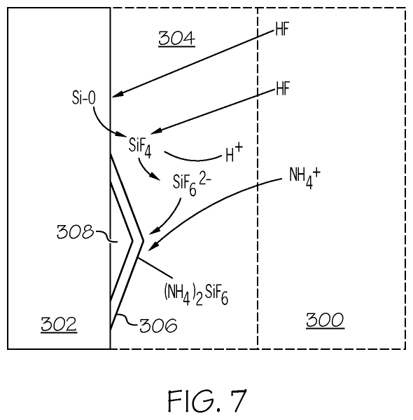

Referring now to FIG. 7, the ammonium bifluoride includes hydrogen fluoride (HF) species and ammonium (NH₄) ions. The etchant 300 reacts with the aluminosilicate glass article 302, which causes HF species from the etchant 300 to diffuse into the aluminosilicate glass article 302 and corrode the Si—O network. SiF₄ is released from the aluminosilicate glass article 302 and reacts with HF to generate SiF₆²⁻ ions. The NH₄ ions from the etchant 300 diffuse to an interface 304 of the etchant 300 and aluminosilicate glass article 302 and react with the SiF₆²⁻ ions to produce ammonium fluorosilicate ((NH₄)₂SiF₆ precipitates. Because these precipitates have low solubility in the etchant 300, they then deposit on the surface of the aluminosilicate glass article 302 to form crystal seeds 306 (e.g., salt crusts).

As the etchant 300 continues to react with the aluminosilicate glass article 302, the crystal seeds 306 grow. Because the crystal seeds 306 are insoluble in the etchant, the crystal seeds 306 serve as an in-situ mask. The crystal seeds 306 seal portions of the surface of the aluminosilicate glass article 302. Glass is etched away around the crystal seeds 306 to generate polyhedral surface features 308. The shape of the polyhedral surface features 308 may be determined by the shape of the crystal seeds 306, which may be altered by varying the composition of the etchant 300 and/or varying the length of time the etchant contacts the aluminosilicate glass article 302.

As such, the ammonium bifluoride present in the etchant 300 acts as a crystallization promoter, encouraging the formation of crystal seeds 306. The amount of ammonium bifluoride in the etchant 300 should be sufficiently high (e.g., greater than or equal to 20 wt %) to ensure formation of the crystal seeds 306. The amount of ammonium fluoride may be limited (less than or equal to 45 wt %) to reduce or prevent undissolved salt that may precipitate out once solubility is reached. Undissolved salt may etch differently than the etchant and may cause a lack of micro-uniformity.

In embodiments, the amount of ammonium bifluoride in the etchant 300 may be greater than or equal to 20 wt %, greater than or equal to 23 wt %, greater than or equal to 25 wt %, or even greater than or equal to 27 wt %. In embodiments, the amount of ammonium bifluoride in the etchant 300 may be less than or equal to 45 wt %, less than or equal to 43 wt %, less than or equal to 40 wt %, less than or equal to 37 wt %, or even less than or equal to 35 wt %. In embodiments, the amount of ammonium bifluoride in the etchant 300 maybe greater than or equal to 20 wt % and less than or equal to 45 wt %, greater than or equal to 20 wt % and less than or equal to 43 wt %, greater than or equal to 20 wt % and less than or equal to 40 wt %, greater than or equal to 20 wt % and less than or equal to 37 wt %, greater than or equal to 20 wt % and less than or equal to 35 wt %, greater than or equal to 23 wt % and less than or equal to 45 wt %, greater than or equal to 23 wt % and less than or equal to 43 wt %, greater than or equal to 23 wt % and less than or equal to 40 wt %, greater than or equal to 23 wt % and less than or equal to 37 wt %, greater than or equal to 23 wt % and less than or equal to 35 wt %, greater than or equal to 25 wt % and less than or equal to 45 wt %, greater than or equal to 25 wt % and less than or equal to 43 wt %, greater than or equal to 25 wt % and less than or equal to 40 wt %, greater than or equal to 25 wt % and less than or equal to 37 wt %, greater than or equal to 25 wt % and less than or equal to 35 wt %, greater than or equal to 27 wt % and less than or equal to 45 wt %, greater than or equal to 27 wt % and less than or equal to 43 wt %, greater than or equal to 27 wt % and less than or equal to 40 wt %, greater than or equal to 27 wt % and less than or equal to 37 wt %, or even greater than or equal to 27 wt % and less than or equal to 35 wt %, or any and all sub-ranges formed from any of these endpoints.

The silicon compound in the etchant 300 may be used to increase the concentration of Si ions (e.g., silica and silica gel) or the concentration of SiF₆ ions (e.g., ammonium hexafluorosilicate, potassium hexafluorosilicate, sodium hexafluorosilicate, or magnesium hexafluorosilicate), thereby speeding up the precipitation of ammonium fluorosilicate on the aluminosilicate glass article 302. In embodiments, the silicon compound may comprise silica, silica gel, ammonium hexaflurosilicate, potassium hexafluorosilicate, sodium hexafluorosilicate, magnesium hexafluorosilicate, or a combination thereof.

The amount of silicon compound in the etchant 300 should be sufficiently high (e.g, greater than or equal to 0.25 wt %) to ensure that the concentration of Si or SiF₆ ions is increased. The amount of silicon compound may be limited (e.g., less than or equal to 10 wt %) so as to not increase the viscosity of the etchant 300 to a point where sufficient coverage and micro-uniformity of the resulting polyhedral surface features are not achieved.

In embodiments, the amount of the silicon compound in the etchant 300 may be greater than or equal to 0.25 wt %, greater than or equal to 0.5 wt %, greater than or equal 0.75 wt %, or even greater than or equal to 1 wt %. In embodiments, the amount of silicon compound in the etchant 300 may be less than or equal to 10 wt %, less than or equal to 8 wt %, less than or equal to 6 wt %, or even less than or equal to 4 wt %. In embodiments, the amount of the silicon compound in the etchant 300 may be greater than or equal to 0.25 wt % and less than or equal to 10 wt %, greater than or equal to 0.25 wt % and less than or equal to 8 wt %, greater than or equal to 0.25 wt % and less than or equal to 6 wt %, greater than or equal to 0.25 wt % and less than or equal to 4 wt %, greater than or equal to 0.5 wt % and less than or equal to 10 wt %, greater than or equal to 0.5 wt % and less than or equal to 8 wt %, greater than or equal to 0.5 wt % and less than or equal to 6 wt %, greater than or equal to 0.5 wt % and less than or equal to 4 wt %, greater than or equal to 0.75 wt % and less than or equal to 10 wt %, greater than or equal to 0.75 wt % and less than or equal to 8 wt %, greater than or equal to 0.75 wt % and less than or equal to 6 wt %, greater than or equal to 0.75 wt % and less than or equal to 4 wt %, greater than or equal to 1 wt % and less than or equal to 10 wt %, greater than or equal to 1 wt % and less than or equal to 8 wt %, greater than or equal to 1 wt % and less than or equal to 6 wt %, or even greater than or equal to 1 wt % and less than or equal to 4 wt %, or any and all sub-ranges formed from any of these endpoints.

The polyhydric alcohol in the etchant 300 may be used to increase the viscosity of the etchant to help regulate the flow of the etchant. The polyhydric alcohol in the etchant 300 may also be used to decrease the dissolvability of ammonium fluorosilicate, thereby increasing the precipitation of ammonium fluorosilicate. In embodiments, the hydrochloric acid may comprise pentaerythritol, ethylene glycol, 1,2-propanediol, 1,4-butanediol, 1,6-hexanediol, neopentyl glycol, diethylene glycol, dipropylene glycol, trimethylolpropane, glycerol, or a combination thereof.

The amount of polyhydric alcohol in the etchant 300 should be sufficiently high (e.g, greater than or equal to 0.5 wt %) to ensure increased etchant viscosity. The amount of polyhydric acid may be limited (e.g., less than or equal to 20 wt %) so as to not increase the viscosity of the etchant 300 to a point were sufficient coverage and micro-uniformity of the resulting polyhedral surface features are not achieved. In embodiments, the amount of polyhydric alcohol in the etchant 300 may be greater than or equal to 0.5 wt %, greater than or equal to 1 wt %, greater than or equal to 1.5 wt %, or even greater than or equal to 2 wt %. In embodiments, the amount of polyhydric alcohol in the etchant 300 may be less than or equal to 20 wt %, less than or equal to 15 wt %, less than or equal to 10 wt %, or even less than or equal to 5 wt %. In embodiments, the amount of polyhydric alcohol in the etchant 300 maybe greater than or equal to 0.5 wt % and less than or equal to 20 wt %, greater than or equal to 0.5 wt % and less than or equal to 15 wt %, greater than or equal to 0.5 wt % and less than or equal to 10 wt %, greater than or equal to 0.5 wt % and less than or equal to 5 wt %, greater than or equal to 1 wt % and less than or equal to 20 wt %, greater than or equal to 1 wt % and less than or equal to 15 wt %, greater than or equal to 1 wt % and less than or equal to 10 wt %, greater than or equal to 1 wt % and less than or equal to 5 wt %, greater than or equal to 1.5 wt % and less than or equal to 20 wt %, greater than or equal to 1.5 wt % and less than or equal to 15 wt %, greater than or equal to 1.5 wt % and less than or equal to 10 wt %, greater than or equal to 1.5 wt % and less than or equal to 5 wt %, greater than or equal to 2 wt % and less than or equal to 20 wt %, greater than or equal to 2 wt % and less than or equal to 15 wt %, greater than or equal to 2 wt % and less than or equal to 10 wt %, or even greater than or equal to 2 wt % and less than or equal to 5 wt %, or any and all sub-ranges formed from any of these endpoints.

The hydrochloric acid present in the etchant 300 functions to dissolve the components of the glass network of the aluminosilicate glass article 302 and form the polyhedral surface features 308. The amount of the hydrochloric acid in the etchant 300 should be sufficiently high (e.g., greater than or equal to 5 wt %) to ensure etching of glass and the formation of the textured glass article. The amount of hydrochloric acid may be limited (e.g., less than or equal to 30 wt %) to ensure polyhedral surface features are produced. When an excessive amount of hydrochloric acid is added, the polyhedral surface features may be corroded to a smaller size, losing their reflective appearance.

In embodiments, the amount of hydrochloric acid in the etchant 300 may be greater than or equal to 5 wt %, greater than or equal to 7 wt %, greater than or equal to 10 wt %, greater than or equal to 13 wt %, or even greater than or equal to 15 wt %. In embodiments, the amount of hydrochloric acid in the etchant 300 may be less than or equal to 30 wt %, less than or equal to 27 wt %, less than or equal to 25 wt %, less than or equal to 23 wt %, or even less than or equal to 20 wt %. In embodiments, the amount of hydrochloric acid in the etchant 300 maybe greater than or equal to 5 wt % and less than or equal to 30 wt %, greater than or equal to 5 wt % and less than or equal to 27 wt %, greater than or equal to 5 wt % and less than or equal to 25 wt %, greater than or equal to 5 wt % and less than or equal to 23 wt %, greater than or equal to 5 wt % and less than or equal to 20 wt %, greater than or equal to 7 wt % and less than or equal to 30 wt %, greater than or equal to 7 wt % and less than or equal to 27 wt %, greater than or equal to 7 wt % and less than or equal to 25 wt %, greater than or equal to 7 wt % and less than or equal to 23 wt %, greater than or equal to 7 wt % and less than or equal to 20 wt %, greater than or equal to 10 wt % and less than or equal to 30 wt %, greater than or equal to 10 wt % and less than or equal to 27 wt %, greater than or equal to 10 wt % and less than or equal to 25 wt %, greater than or equal to 10 wt % and less than or equal to 23 wt %, greater than or equal to 10 wt % and less than or equal to 20 wt %, greater than or equal to 13 wt % and less than or equal to 30 wt %, greater than or equal to 13 wt % and less than or equal to 27 wt %, greater than or equal to 13 wt % and less than or equal to 25 wt %, greater than or equal to 13 wt % and less than or equal to 23 wt %, greater than or equal to 13 wt % and less than or equal to 20 wt %, greater than or equal to 15 wt % and less than or equal to 30 wt %, greater than or equal to 15 wt % and less than or equal to 27 wt %, greater than or equal to 15 wt % and less than or equal to 25 wt %, greater than or equal to 15 wt % and less than or equal to 23 wt %, or even greater than or equal to 15 wt % and less than or equal to 20 wt %, or any and all sub-ranges formed from any of these endpoints.

The water present in the etchant 300 acts as a solvent. In embodiments, the amount of water in the etchant 300 maybe greater than or equal to 25 wt %, greater than or equal to 30 wt %, greater than or equal to 35 wt %, or even greater than or equal to 40 wt %. In embodiments, the amount of water in the etchant 300 may be less than or equal to 60 wt %, less than or equal to 55 wt %, or even less than or equal to 50 wt %. In embodiments, the amount of water in the etchant 300 may be greater than or equal to 25 wt % and less than or equal to 60 wt %, greater than or equal to 25 wt % and less than or equal to 55 wt %, greater than or equal to 25 wt % and less than or equal to 50 wt %, greater than or equal to 30 wt % and less than or equal to 60 wt %, greater than or equal to 30 wt % and less than or equal to 55 wt %, greater than or equal to 30 wt % and less than or equal to 50 wt %, greater than or equal to 35 wt % and less than or equal to 60 wt %, greater than or equal to 35 wt % and less than or equal to 55 wt %, greater than or equal to 35 wt % and less than or equal to 50 wt %, greater than or equal to 40 wt % and less than or equal to 60 wt %, greater than or equal to 40 wt % and less than or equal to 55 wt %, or even greater than or equal to 40 wt % and less than or equal to 50 wt % or any and all sub-ranges formed from any of these endpoints.

In embodiments, the etchant 300 disclosed herein may have a relatively high viscosity and be a slurry due to the presence and amounts of ammonium bifluoride and the silicon compound. The relatively high viscosity of the etchant 300 may help regulate the flow of the etchant, leading to sufficient coverage and micro-uniformity of the resulting polyhedral surface features. In embodiments, a weight ratio of a sum of the ammonium bifluoride and the silicon compound to a sum of the hydrochloric acid, the water, and the polyhydric alcohol may be from 0.3 to 0.9 or even from 0.3 to 0.6.

In embodiments, the etchant 300 may comprise greater than or equal to 25 wt % and less than or equal to 40 wt % ammonium bifluoride; greater than or equal to 0.5 wt % and less than or equal to 4 wt % silica gel; greater than or equal to 13 wt % and less than or equal to 23 wt % hydrochloric acid; greater than or equal to 35 wt % and less than or equal to 25 wt % water, and greater than or equal to 1 wt % and less than or equal to 15 wt % glycerol.

### Method of Forming Textured Glass Article

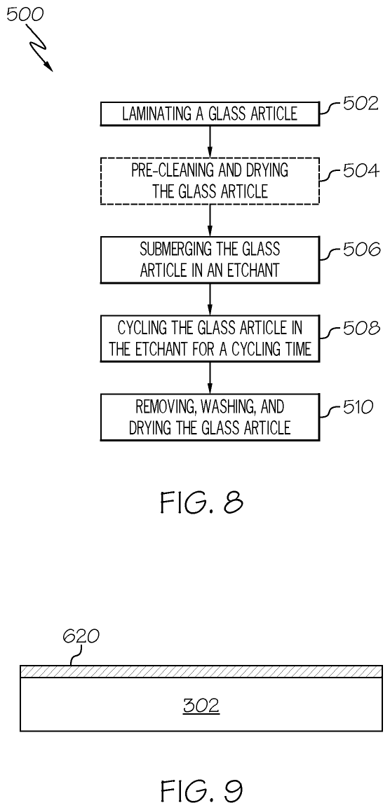

Referring now to FIGS. 8 and 9, in embodiments, a method 500 of forming a textured glass article beings at block 502 with laminating an aluminosilicate glass article 302 with a laminate 620. The aluminosilicate glass article 302 may be in the form of a plate. In embodiments, the laminate 620 may be a polyethylene film with an adhesive layer. In embodiments, laminating the aluminosilicate glass article 302 may be conducted in a roller lamination machine.

Referring back to FIG. 8, in embodiments, the method 500 may optionally continue at block 504 with pre-cleaning (e.g., in an aqueous solution followed by rinsing (e.g., with DI water)) and drying (e.g., in an oven) the aluminosilicate glass article 302.

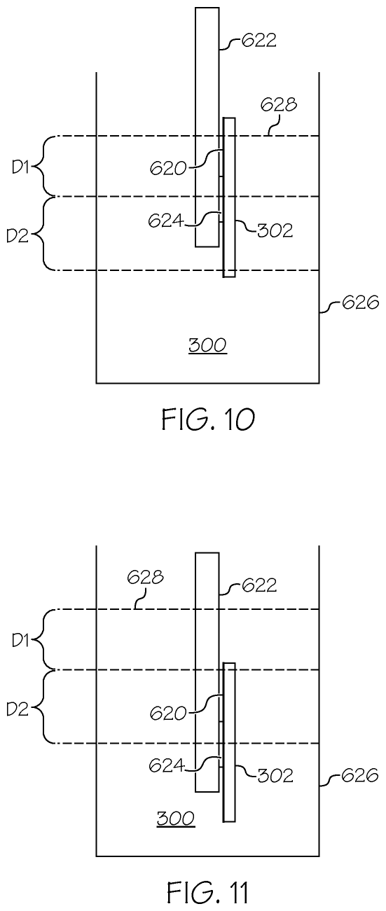

Referring back to FIG. 8 and now to FIG. 10, the method 500 continues at block 506 with submerging the aluminosilicate glass article 302 in an etchant 300. In embodiments, the etchant 300 may be prepared by blending the components in powder form by hand mill and pre-mixing and stirring the components in liquid/solvent form to a homogenous state. The mixture of powder and liquid may be performed with pouring and stirring. The resulting etchant 300 may be aged for greater than or equal to 2 hours prior to submersion of the aluminosilicate glass article 302.

In embodiments, a temperature of the etchant 300 may be greater than or equal to 10° C. and less than or equal to 30° C. In embodiments, the temperature of the etchant 300 may be greater than or equal to 10° C., greater than or equal to 12° C., greater than or equal to 14° C., or even greater than or equal to 16° C. In embodiments, the temperature of the etchant 300 may be less than or equal to 30° C., less than or equal to 28° C., less than or equal to 26° C., or even less than or equal to 24° C. In embodiments, the temperature of the etchant 300 may be greater than or equal to 10° C. and less than or equal to 30° C., greater than or equal to 10° C. and less than or equal to 28° C., greater than or equal to 10° C. and less than or equal to 26° C., greater than or equal to 10° C. and less than or equal to 24° C., greater than or equal to 12° C. and less than or equal to 30° C., greater than or equal to 12° C. and less than or equal to 28° C., greater than or equal to 12° C. and less than or equal to 26° C., greater than or equal to 12° C. and less than or equal to 24° C., greater than or equal to 14° C. and less than or equal to 30° C., greater than or equal to 14° C. and less than or equal to 28° C., greater than or equal to 14° C. and less than or equal to 26° C., greater than or equal to 14° C. and less than or equal to 24° C., greater than or equal to 16° C. and less than or equal to 30° C., greater than or equal to 16° C. and less than or equal to 28° C., greater than or equal to 16° C. and less than or equal to 26° C., or even greater than or equal to 16° C. and less than or equal to 24° C., or any and all sub-ranges formed from any of these endpoints.

In embodiments, as shown in FIG. 10, the aluminosilicate glass article 302 may be secured to an arm 622 to facilitate submerging the aluminosilicate glass article 302 in the etchant 300. For example, in embodiments, an adhesive or suction cup 624 may be disposed between the laminate 620 and the arm 622 to secure the aluminosilicate glass article 302 to the arm 622. The arm 622 may be lowered into a tank 626 containing etchant 300, thereby submerging the aluminosilicate glass article 302 in the etchant 300.

Referring back to FIGS. 8 and 10 and now to FIG. 11, the method continues at block 508 with cycling the aluminosilicate glass article 302 in the etchant 300 between the upper submerging depth D1 (as shown in FIG. 10) and a lower submerging depth D2 (as shown in FIG. 11) for a cycling time. In embodiments, the aluminosilicate glass article 302 is cycled by moving arm 622 in a repetitive upward and downward motion. The lower submerging depth D2 is deeper than the upper submerging depth D1 relative to the surface 628 of the etchant 300.

In embodiments, the cycling may be conducted at a speed greater than or equal to 5 cm/s and less than or equal to 30 cm/s. In embodiments, the cycling speed may be greater than or equal to 5 cm/s or even greater than or equal to 10 cm/s. In embodiments, the cycling speed may be less than or equal to 30 cm/s, less than or equal to 25 cm/s, or even less than or equal to 20 cm/s. In embodiments, the cycling may be conducted at a speed greater than or equal to 5 cm/s and less than or equal to 30 cm/s, greater than or equal to 5 cm/s and less than or equal to 25 cm/s, greater than or equal to 5 cm/s and less than or equal to 20 cm/s, greater than or equal to 10 cm/s and less than or equal to 30 cm/s, greater than or equal to 10 cm/s and less than or equal to 25 cm/s, or even greater than or equal to 10 cm/s and less than or equal to 20 cm/s, or any and all sub-ranges formed from any of these endpoints.

Cycling helps achieve sufficient coverage and micro-uniformity of the polyhedral surface features. In embodiments, the cycling time may be greater than or equal to 60 s and less than or equal to 600 s. In embodiments, the cycling time may be greater than or equal to 60 s, greater than or equal to 120 s, greater than or equal to 180 s, or even greater than or equal to 240 s. In embodiments, the cycling time may be less than or equal to 600 s, less than or equal to 480 s, or even less than or equal to 360 s. In embodiments, the cycling time may be greater than or equal to 60 s and less than or equal to 600 s, greater than or equal to 60 s and less than or equal to 480 s, greater than or equal to 60 s and less than or equal to 360 s, greater than or equal to 120 s and less than or equal to 600 s, greater than or equal to 120 s and less than or equal to 480 s, greater than or equal to 120 s and less than or equal to 360 s, greater than or equal to 180 s and less than or equal to 600 s, greater than or equal to 180 s and less than or equal to 480 s, or even greater than or equal to 180 s and less than or equal to 360 s, or any and all sub-ranges formed from any of these endpoints.

Referring back to FIG. 8, the method 500 continues at block 510 with removing the aluminosilicate glass article 302 from the etchant 300, washing the aluminosilicate glass article 302 to remove the etchant 300 and crystal seeds 306 from the surface, and drying the article to form the textured glass article having polyhedral surface features as shown in FIG. 4. The aluminosilicate glass article 302 may be removed from arm 622. In embodiments, the etchant may be rinsed off the aluminosilicate glass article 302 with deionized (DI) water. In embodiments, crystal seeds 306 adhering to the aluminosilicate glass article 302 may be removed or scratched off by, for example, a scrubber sponge. In embodiments, the laminate 620 may be removed. In embodiments, the aluminosilicate glass article 302 may be dried in ambient condition or in an oven.

### Coating

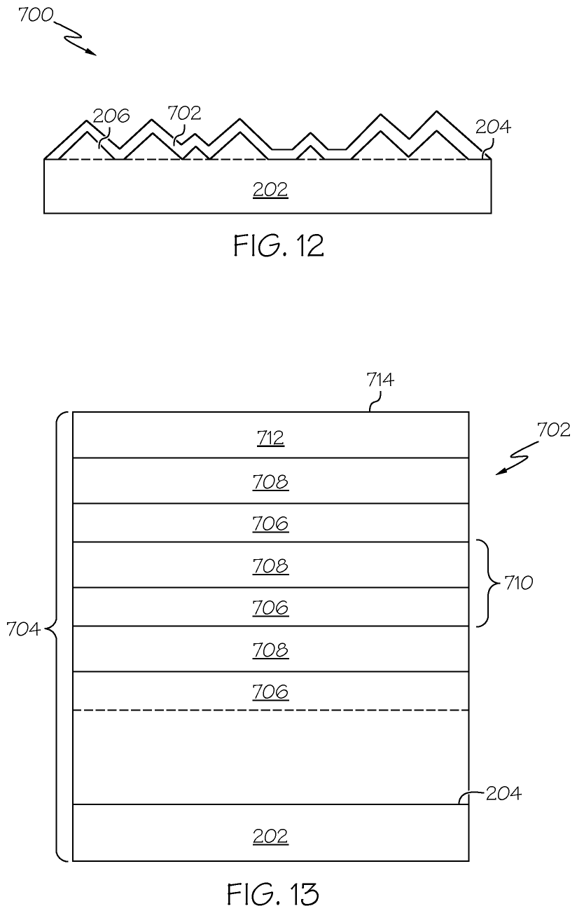

Referring now to FIG. 12, a coated textured glass article 700 as described herein comprises a coating 702 (e.g., an anti-reflective coating 702) disposed on the first surface 204 of the glass body 202 and the plurality of polyhedral surface features 206. As described below, the coating 702 provides enhanced reflectance and hardness. Moreover, the coating 702 may be modified to provide desired color properties.

The coating 702 includes at least one layer of at least one material. The term “layer” may include a single layer or may include one or more sub-layers. Such sub-layers may be in direct contact with one another. The sub-layers may be formed from the same material or two or more different materials. In embodiments, such sub-layers may have intervening layers of different materials disposed therebetween. In embodiments, a layer may include one or more contiguous and uninterrupted layers and/or one or more discontinuous and interrupted layers (i.e., a layer having different materials formed adjacent to one another. A layer or sub-layers may be formed by any known method in the art, including discrete deposition or continuous deposition processes. In embodiments, the layer may be formed using only continuous deposition processes, or, alternatively, only discrete deposition processes.

A thickness of the coating 702 contributes to the enhanced hardness of the coated textured glass article 700. In embodiments, a thickness of coating 702 maybe greater than or equal to 1 μm or even greater than or equal to 2 μm. In embodiments, a thickness of coating 702 may be less than or equal to 10 μm or even less than or equal to 5 μm. In embodiments, a thickness of coating 702 may be greater than or equal to 1 μm and less than or equal to 10 μm, greater than or equal to 1 μm and less than or equal to 5 μm, greater than or equal to 2 μm and less than or equal to 10 μm, or even greater than or equal to 2 μm and less than or equal to 5 μm, or any and all sub-ranges formed from any of these endpoints.

As used herein, the term “dispose” includes coating, depositing, and/or forming a material onto a surface using any known method in the art. The disposed material may constitute a layer, as defined herein. The phrase “disposed on” includes the instance of forming a material onto a surface such that the material is in direct contact with the surface and also includes the instance where the material is formed on a surface, with one or more intervening material(s) between the disposed material and the surface. The intervening material(s) may constitute a layer, as defined herein.

The coating 702 may be formed using various deposition methods such as vacuum deposition techniques, for example, chemical vapor deposition (e.g., plasma enhanced chemical vapor deposition (PECVD), low-pressure chemical vapor deposition, atmospheric pressure chemical vapor deposition, and plasma-enhanced atmospheric pressure chemical vapor deposition), physical vapor deposition (e.g., reactive od nonreactive sputtering, metal-mode reactive sputtering or laser ablation), thermal or e-beam evaporation and/or atomic layer deposition. Liquid-based methods may also be used such as spraying, dipping, spin coating or slot coating (for example, using sol-gel material).

Referring now to FIG. 13, the coating 702 includes a multi-layer interference stack 704. In embodiments, the multi-layer interference stack 704 may include a plurality of layers 706, 708. In embodiments, the plurality of layers 706, 708 may be characterized as having different refractive indices from each other. In embodiments, the multi-layer interference stack 704 may include at least one low refractive index layer 706 and at least one high refractive index layer 708. The term “high refractive index,” as used herein, includes a range from 1.7 to 2.5. The term “low refractive index,” as used herein, includes a range from 1.3 to 1.6.

In embodiments, the difference in refractive index of the low refractive index layer and the high refractive index layer may be greater than or equal to 0.01, greater than or equal to 0.05, greater than or equal to 0.1, greater than or equal to 0.3, or even greater than or equal to 0.5.

The thicknesses of the at least one low refractive index layer 706 and at least one high refractive index layer 708 may be designed to lead to destructive interference (i.e., low reflection) or constructive interference (i.e., high reflection). Adjusting the number, thickness, and materials of the at least one low refractive index layer 706 and the at least one high refractive index layer 708 helps to enhance the reflectance.

In embodiments, the multi-layer interference stack 704 may include at least one period 710. A single period 710 may include a low refractive index layer 706 and a high refractive index layer 708, such that when a plurality of periods are provided, the low refractive index layer 706 and the high refractive index layer 708 appear to alternate along the physical thickness of the multi-layer interference stack 704. In the example in FIG. 13, the multi-layer interference stack 704 includes three periods. In embodiments, the multi-layer interference stack 704 may include from 1 to 20 periods. In embodiments, the multi-layer interference stack 704 may include greater than 1 period, greater than 2 periods, greater than 3 periods, greater than or equal to 4 periods, or even greater than or equal to 5 periods. In embodiments, the multi-layer interference stack 704 may include less than or equal to 20 periods, less than or equal to 18 periods, less than or equal to 16 periods, less than or equal to 14 periods, or even less than or equal to 12 periods. In embodiments, the multi-layer interference stack 704 may include from 1 to 20 periods, from 1 to 18 periods, from 1 to 16 periods, from 1 to 14 periods, from 1 to 12 periods, from 2 to 20 periods, from 2 to 18 periods, from 2 to 16 periods, from 2 to 14 periods, from 2 to 12 periods, from 3 to 20 periods, from 3 to 18 periods, from 3 to 16 periods, from 3 to 14 periods, from 3 to 12 periods, from 4 to 20 periods, from 4 to 18 periods, from 4 to 16 periods, from 4 to 14 periods, from 4 to 12 periods, from 5 to 20 periods, from 5 to 18 periods, from 5 to 16 periods, from 5 to 14 periods, or even from 5 to 12 periods, or any and all sub-ranges formed from any of these endpoints.

Exemplary materials suitable for use in the multi-layer interference stack 704 include SiO₂, Al₂O₃, GeO₂, SiO, AlOₓN_{y}, AlN, SiNₓ, SiOₓN_{y}, SiᵤAlᵥOₓN_{y}, Ta₂O₅, Nb₂O₅, TiO₂, ZrO₂, TiN, MgO, MgF₂, CaF₂, SnO₂, HfO₂, Y₂O₃, MoO₃, DyF₃, YF₃, CeF₃, polymers, fluoropolymers, plasma-polymerized polymers, siloxane polymers, silsequioxanes, polyimides, fluorinated polyimides, polyetherimide, polyethersulfone, polyphenylsulfone, polycarbonate, polyethylene terephthalate, polyethylene naphthalate, acrylic polymers, urethane polymers, polymethylmethacrylate, and other materials known in the art, where subscripts “u,” “x,” and “y” are from 0 to 1. In embodiments, the low refractive index layer 706 may comprise SiO₂, Al₂O₃, GeO₂, SiO, AlOₓN_{y}, SiOₓNᵤ, SiAlₓO_{y}, SiᵤAlᵥOₓN_{y}, MgO, MgAl₂O₄, MgF₂, BaF₂, CaF₂, DyF₃, YbF₃, CeF₃, or a combination thereof, where subscripts “u,” “x,” and “y” are from 0 to 1. In embodiments, the nitrogen content of the materials for use in the low refractive index layer may be minimized (e.g., in materials such as Al₂O₃ and MgAl₂O₄) to achieve a lower refractive index and/or to achieve a lower absorption. In embodiments, the high refractive index layer 708 may comprise SiᵤAlᵥOₓN_{y}, Ya₂O₅, Nb₂O₅, AlN, Si₃N₄, AlOₓN_{y}, SiOₓN_{y}, HfO₂, TiO₂, ZrO₂, Y₂O₃, Al₂O₃, MoO₃, diamond-like carbon, or a combination thereof, wherein subscripts “u,” “x,” and “y” are from 0 to 1. In embodiments, the oxygen content of the materials for the high refractive index layer may be minimized (e.g, in SiNx or AlNx materials) to achieve a higher hardness.

In embodiments, the low refractive index layer 706 may have a thickness greater than or equal to 2 nm and less than or equal to 200 nm. In embodiments, the low refractive index layer 706 may have a thickness greater than or equal to 2 nm, greater than or equal to 5 nm, greater than or equal to 10 nm, or even greater than or equal to 25 nm. In embodiments, the low refractive index layer 706 may have a thickness less than or equal to 200 nm, less than or equal to 150 nm, or even less than or equal to 100 nm. In embodiments, the low refractive index layer may have a thickness greater than or equal to 2 nm and less than or equal to 200 nm, greater than or equal to 2 nm and less than or equal to 150 nm, greater than or equal to 2 nm and less than or equal to 100 nm, greater than or equal to 5 nm and less than or equal to 200 nm, greater than or equal to 5 nm and less than or equal to 150 nm, greater than or equal to 5 nm and less than or equal to 100 nm, greater than or equal to 10 nm and less than or equal to 200 nm, greater than or equal to 10 nm and less than or equal to 150 nm, greater than or equal to 10 nm and less than or equal to 100 nm, greater than or equal to 25 nm and less than or equal to 200 nm, greater than or equal to 25 nm and less than or equal to 150 nm, or even greater than or equal to 25 nm and less than or equal to 100 nm, or any and all sub-ranges formed from any of these endpoints.

In embodiments, the high refractive index layer 708 may have a thickness greater than or equal to 5 nm and less than or equal to 5000 nm. In embodiments, the high refractive index layer 708 may have a thickness greater than or equal to 5 nm, greater than or equal to 10 nm, or even greater than or equal to 25 nm. In embodiments, the high refractive index layer 708 may have a thickness less than or equal to 5000 nm, less than or equal to 2500 nm, less than or equal to 1000 nm, less than or equal to 500 nm, or even less than or equal to 250 nm. In embodiments, the high refractive index layer have a thickness greater than or equal to 5 nm and less than or equal to 5000 nm, greater than or equal to 5 nm and less than or equal to 2500 nm, greater than or equal to 5 nm and less than or equal to 1000 nm, greater than or equal to 5 nm and less than or equal to 500 nm, greater than or equal to 5 nm and less than or equal to 250 nm, greater than or equal to 10 nm and less than or equal to 5000 nm, greater than or equal to 10 nm and less than or equal to 2500 nm, greater than or equal to 10 nm and less than or equal to 1000 nm, greater than or equal to 10 nm and less than or equal to 500 nm, greater than or equal to 10 nm and less than or equal to 250 nm, greater than or equal to 25 nm and less than or equal to 5000 nm, greater than or equal to 25 nm and less than or equal to 2500 nm, greater than or equal to 25 nm and less than or equal to 1000 nm, greater than or equal to 25 nm and less than or equal to 500 nm, or even greater than or equal to 25 nm and less than or equal to 250 nm, or any and all sub-ranges formed from any of these endpoints.

In embodiments, the amount of low refractive index material in the coating may be minimized. Without being bound by theory, the low refractive index material is generally also a lower-hardness material, owing to the nature of atomic bonding and electron densities that simultaneously affect refractive index and hardness. Thus, minimizing such the low refractive index material may maximize hardness, while maintaining the reflectance and color performance described herein. In embodiments, expressed as a fraction of the thickness of the coating 702, the low refractive index material may comprise less than or equal to 60%, less than or equal to 50%, less than or equal to 40%, less than or equal to 30%, less than or equal to 20%, less than or equal to 10%, or even less than or equal to 5% of the thickness of the coating.

Without being bound by theory, the high refractive index material may also generally a higher-hardness material. Accordingly, inclusion of a high refractive index material may not only enhance reflectance, but may also enhance hardness.

Without being bound by theory, a thick high refractive index layer having a relatively higher hardness effectively shields the layers underneath (or between the thick refractive index layer and the glass body) from scratches. This thick high refractive index layer maybe referred to as a scratch resistant layer. The physical thickness of the scratch resistant layer may be in the range from about 1 nm to about 5 μm. In some embodiments, the physical thickness of the scratch resistant coating may be in the range from about 1 nm to about 3 μm, from about 1 nm to about 2.5 μm, from about 1 nm to about 2 μm, from about 1 nm to about 1.5 μm, from about 1 nm to about 1 μm, from about 1 nm to about 0.5 μm, from about 1 nm to about 0.2 μm, from about 1 nm to about 0.1 μm, from about 1 nm to about 0.05 μm, from about 5 nm to about 0.05 μm, from about 10 nm to about 0.05 μm, from about 15 nm to about 0.05 μm, from about 20 nm to about 0.05 μm, from about 5 nm to about 0.05 μm, from about 200 nm to about 3 μm, from about 400 nm to about 3 μm, from about 800 nm to about 3 μm, and all ranges and sub-ranges therebetween. In some embodiments, the physical thickness of the scratch resistant coating may be in the range from about 1 nm to about 25 nm. In some instances, the scratch-resistant layer may include a nitride or an oxy-nitride material and may have a thickness of about 200 nm or greater, 500 nm or greater or about 1000 nm or greater.

In embodiments, the multi-layer interference stack 704 may include an additional capping layer 712. The additional capping layer 712 may include a lower refractive index material than the high refractive index layer 708. In embodiments, the capping layer 712 may be a low-friction layer, an oleophobic coating, or an easy-to-clean coating. For example, in embodiments, the capping layer 712 may include SiO₂, an oleophobic or low-friction layer, or a combination of SiO₂ and an oleophobic material. Exemplary low-friction layers may include diamond-like carbon, such materials exhibiting a coefficient of friction less than 0.4, less than 0.3, less than 0.2, or even less than 0.1.

In embodiments, the addition of the capping layer 712 (e.g., a lower refractive index layer) having a low thickness (e.g., less than or equal to 200 nm) relative to the thick high refractive index layer (e.g., greater than or equal to 500 nm) has minimal influence on the reflectance and color performance of the textured glass article. In embodiments, the capping layer 712 may have a thickness greater than 0 nm or even greater than or equal to 1 nm. In embodiments, the capping layer 712 may have a thickness less than or equal to 200 nm, less than or equal to 150 nm, less than or equal to 100 nm, or less than or equal to 50 nm, or even less than or equal to 25 nm. In embodiments, the capping layer 712 may have a thickness greater than 0 nm and less than or equal to 200 nm, greater than 0 nm and less than or equal to 150 nm, greater than 0 nm and less than or equal to 100 nm, greater than 0 nm and less than or equal to 50 nm, greater than 0 nm and less than or equal to 25 nm, greater than or equal to 1 nm and less than or equal to 200 nm, greater than or equal to 1 nm and less than or equal to 150 nm, greater than or equal to 1 nm and less than or equal to 100 nm, greater than or equal to 1 nm and less than or equal to 50 nm, or even greater than or equal to 1 nm and less than or equal to 25 nm, or any and all sub-ranges formed from any of these endpoints.

In embodiments, the multi-layer interference stack 704 comprises an outer surface 714 opposite the first surface of the glass body 202.

As described herein, the coating 702 enhances the hardness of the coated textured glass article 700, due, at least in part, to the thickness of the coating 702 and the inclusion of a high refractive index layer 708. In embodiments, the coated textured glass article 700 may comprise a hardness greater than or equal to 10 GPa. In embodiments, the coated textured glass article 700 may comprise a hardness greater than or equal to 10 GPa, greater than or equal to 12 GPa, greater than or equal to 15 GPa, greater than or equal to 18 GPa, or even greater than or equal to 20 GPa. In embodiments, the coated textured glass article 700 may comprise a hardness less than or equal to less than or equal to 35 GPa, less than or equal to 30 GPa, or even less than or equal to 25 GPa. In embodiments, the coated textured glass article 700 may comprise a hardness greater than or equal to 10 GPa and less than or equal to 35 GPa, greater than or equal to 10 GPa and less than or equal to 30 GPa, greater than or equal to 10 GPa and less than or equal to 25 GPa, greater than or equal to 12 GPa and less than or equal to 35 GPa, greater than or equal to 12 GPa and less than or equal to 30 GPa, greater than or equal to 12 GPa and less than or equal to 25 GPa, greater than or equal to 15 GPa and less than or equal to 35 GPa, greater than or equal to 15 GPa and less than or equal to 30 GPa, greater than or equal to 15 GPa and less than or equal to 25 GPa, greater than or equal to 18 GPa and less than or equal to 35 GPa, greater than or equal to 18 GPa and less than or equal to 30 GPa, greater than or equal to 18 GPa and less than or equal to 25 GPa, greater than or equal to 20 GPa and less than or equal to 35 GPa, greater than or equal to 20 GPa and less than or equal to 30 GPa, or even greater than or equal to 20 GPa and less than or equal to 25 GPa, or any and all sub-ranges formed from any of these endpoints.

In addition to enhanced hardness, the number, thickness, and material of the coating 702 described herein may be adjusted to enhance reflectance of the textured coated glass article. In embodiments, the article may comprise a single average photopic light reflectance greater than or equal to 4%. In embodiments, the coated textured glass article 700 may comprise a single average phototopic light reflectance greater than or equal to 7%. In embodiments, the coated textured glass article 700 may comprise a single average phototopic light reflectance greater than or equal to 10%. In embodiments, the coated textured glass article 700 may comprise a single average phototopic light reflectance greater than or equal to 20%. In embodiments, the coated textured glass article 700 comprises a single average phototopic light reflectance greater than or equal to 4%, greater than or equal to 7%, greater than or equal to 10%, or even greater than or equal to 20%. In embodiments, the coated textured glass article 700 may comprise a single average phototopic light reflectance less than or equal to 60%, less than or equal to 50%, or even less than or equal to 40%. In embodiments, the coated textured glass article 700 may comprise a single average phototopic light reflectance greater than or equal to 4% and less than or equal to 60%, greater than or equal to 4% and less than or equal to 50%, greater than or equal to 4% and less than or equal to 40%, greater than or equal to 7% and less than or equal to 60%, greater than or equal to 7% and less than or equal to 50%, greater than or equal to 7% and less than or equal to 40%, greater than or equal to 10% and less than or equal to 60%, greater than or equal to 10% and less than or equal to 50%, greater than or equal to 10% and less than or equal to 40%, greater than or equal to 20% and less than or equal to 60%, greater than or equal to 20% and less than or equal to 50%, or even greater than or equal to 20% and less than or equal to 40%, or any and all sub-ranges formed from any of these endpoints.

Optical interference between reflected waves from the coating 702/air interface and the coating 702/glass body 202 interface may lead to spectral reflectance oscillations that create an apparent color. Color properties and the resulting apparent color maybe tuned by modifying thickness and materials of the layers of the multilayer interference stack.

The apparent color may be more pronounced in reflection. In embodiments, the coated textured glass article 700 may comprise a peak single side light reflectance greater than or equal to 25%. In embodiments, the coated textured glass article 700 may comprise a peak single side light reflectance greater than or equal to 40%. In embodiments, the coated textured glass article 700 may comprise a peak single side light reflectance greater than or equal to 50%. In embodiments, the coated textured glass article 700 may comprise a peak single side light reflectance greater than or equal to 25%, greater than or equal to 40%, or even greater than or equal to 50%. In embodiments, the coated textured glass article 700 may comprise a peak single side light reflectance less than or equal to 80% or even less than or equal to 70%. In embodiments, the coated textured glass article 700 may comprise greater than or equal to 25% and less than or equal to 80%, greater than or equal to 25% and less than or equal to 70%, greater than or equal to 40% and less than or equal to 80%, greater than or equal to 40% and less than or equal to 70%, greater than or equal to 50% and less than or equal to 80%, or even greater than or equal to 50% and less than or equal to 70%, or any and all sub-ranges formed from any of these endpoints.

The location of the peak single side light reflectance indicates the apparent color of the coated textured glass article. For example, in embodiments, the article may comprise a peak single side light reflectance from 520 nm to 560 nm, as measured at the outer surface at an incident illumination angle of 6°, referenced to normal incidence, over a wavelength range from 400 nm to 700 nm. Reflected light in the 520 nm to 560 nm range visually appears as green.

In embodiments, the coated textured glass article may have an article reflectance color coordinate L* greater than or equal to 20 and less than or equal to 90, as measured under D65 illumination and a 100 standard observer angle. In embodiments, the coated textured glass article comprises at least one of article reflectance color coordinates a* and b* greater than or equal to −30 and less than or equal to 30, as measured under D65 illumination and a 100 standard observer angle.

In embodiments, the angular color shifts in reflection with viewing angle due to a shift in the spectral reflectance oscillations with incident illumination angle. In embodiments, the coated textured glass article may exhibit an angular color shift greater than or equal to 5, as measured at an incident illumination angle greater than or equal to 20 degrees, referenced to normal incidence, under D65 illumination. The angular color shift is calculated using the equation √((a*₂−a*₁)²+(b*₂−b*₁)²), with a*₁, and b*₁ representing the coordinates of the article when viewed at normal incidence and a*₂, and b*₂ representing the coordinates of the article when viewed at the incident illumination angle.

In embodiments, the coated article may also exhibit a reference point color shift, which is used here to simply describe an absolute color that is not neutral, i.e. shifted away from the neutral color described by the origin a*,b*=0,0 in the CIELAB color space, and defined by the equation (reference point color shift)=(a*²+b*²). This reference color shift maybe independent of viewing angle, or may also be combined with an angular color shift. In embodiments, the coated textured glass article may exhibit a reference point color shift (for first-surface reflected color) greater than or equal to 2, greater than or equal to 5, greater than or equal to 10, or greater than or equal to 20, as measured at a normal incidence (or at an angle from 0-20 degrees) under D65 illumination. In embodiments, the coated textured glass article may also exhibit a reference point color shift (for first-surface reflected color) that is less than or equal to 60, less than or equal to 40, or less than or equal to 30, as measured at a normal incidence (or at an angle from 0-20 degrees) under D65 illumination.

Other suitable arrangements, materials, and properties of the multi-layer interference stack 704 are described in U.S. Pat. Nos. 9,079,802B2, 9,359,261B2, 10,444,408B2, 10,162,084B2, 9,684,097B2, 9,335,444B2, and 10,416,352B2, which are incorporated herein in their entirety by reference.

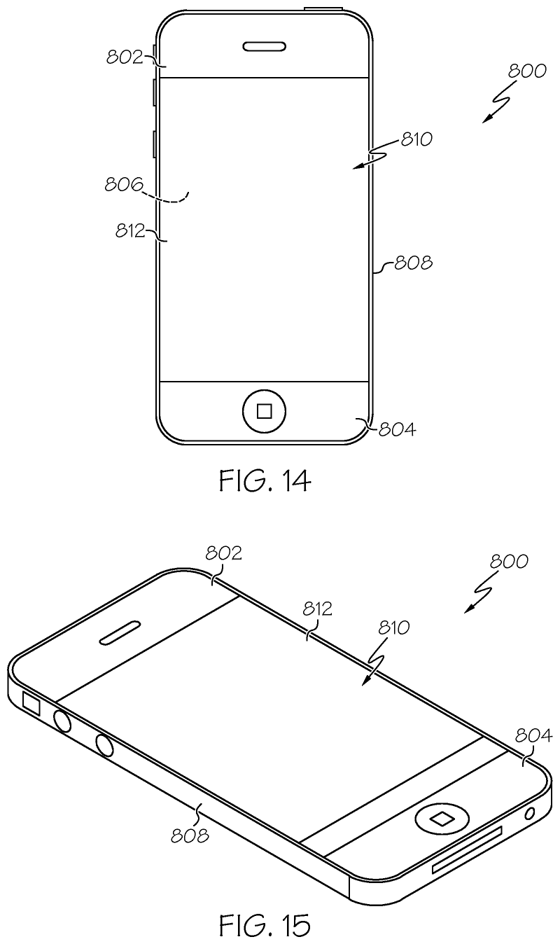

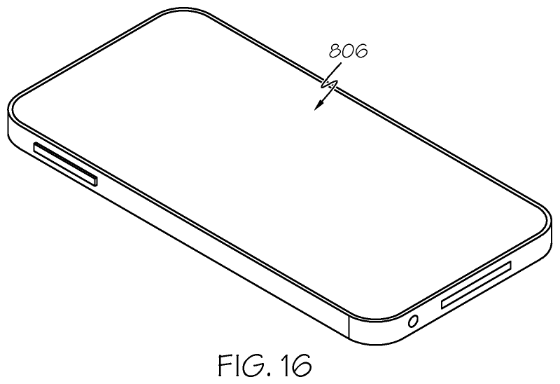

The coated textured glass articles described herein may be used for a variety of applications including, for example, back cover applications in consumer or commercial electronic devices such as smartphones, tablet computers, personal computers, ultrabooks, televisions, and cameras. An exemplary article incorporating any of the coated textured glass articles disclosed herein is shown in FIGS. 14-16. Specifically, FIGS. 14-16 show a consumer electronic device 800 including a housing 802 having front 804, back 806, and side surfaces 808; electrical components (not shown) that are at least partially inside or entirely within the housing and including at least a controller, a memory, and a display 810 at or adjacent to the front surface of the housing; and a cover substrate 812 at or over the front surface of the housing such that it is over the display. In embodiments, a portion of housing 802, such as the back 806, may include any of the coated textured glass articles disclosed herein.

### Examples

In order that various embodiments be more readily understood, reference is made to the following examples, which illustrate various embodiments of the coated textured glass articles described herein.

### Textured Glass Article (i.e., Prior to Disposing a Coating Thereon)

The compositions of Glass Articles GA and GB (in mol %) treated as described below are shown in Table 1.

TABLE 1

| Glass Article | GA | GB |
|---|---|---|
| SiO₂ | 64.40 | 58.65 |
| Al₂O₃ | 15.90 | 17.85 |
| P₂O₅ | 1.25 | 1.47 |
| B₂O₃ | — | 4.22 |
| MgO | — | 1.19 |
| ZnO | 1.20 | — |
| Li₂O | 6.30 | 7.70 |
| Na₂O | 11.00 | 8.72 |
| K₂O | — | 0.07 |
| TiO₂ | — | 0.10 |

Table 2 shows the composition of Example Etchants EA and EB (in wt %).

TABLE 2

| | Example | Example |
|---|---|---|
| Etchant | Etchant EA | Etchant EB |
| NH₄HF₂ | 29.75 | 32.86 |
| SiO₂ gel | 0.61 | 0.84 |
| HCl | 18.80 | 17.24 |
| H₂O | 41.37 | 47.07 |
| C₃H₈O₃ | 9.47 | 1.99 |

Table 3 shows the properties of Example Textured Articles TA and TB formed as described in Examples 1 and 2 below (i.e., prior to disposing a coating thereon).

TABLE 3

| | Example | Example |
|---|---|---|
| | Textured | Textured |
| | Article TA | Article TB |
| Surface feature size (μm) | 115 | 140 |
| Surface feature height (μm) | 13 | 30 |
| Triangular pyramid | 15.0 | 18.5 |
| facet angle (°) | | |
| Quadrangular pyramid | 15.0 | 19.0 |
| facet angle (°) | | |
| Surface roughness (μm) | 4.0 | 6.0 |

### Example 1—Example Textured Article TA (Etchant EA and Glass Article GA)

To obtain Etchant EA, 153 g blended powder including 98.0 wt % NH₄HF₂ and 2.5 wt % SiO₂ gel was obtained by hand mill. 351 g pre-mixed solvent including 27.0 wt % HCl, 59.4 wt % H₂O, and 13.6 wt % C₃H₈O₃ was obtained and stirred adequately. The mixture of powder and solvent was performed at 24° C. The etchant was cooled to 16° C.

Glass Article GA was cut to 50×50 mm size and laminated on one side. The laminated Glass Article GA underwent a 10 min ultrasonic treatment in 30% Parker aqueous solution, followed by adequate rinsing with running DI water. Thereafter, Glass Article GA was dried at 60° C. in an oven, followed by placement in ambient condition until Glass Article GA cooled to 24° C.

Glass Article GA was submerged and cycled in Etchant EA for a period of 120 s and at a cycling speed of 10 cm/s. The temperature of Etchant EA was 16° C.

Etched Glass Article GA was flushed with running DI water. The precipitates on the etched glass article were removed by scratching and the laminate was peeled off. The glass article was placed in a 60° C. oven until dry.

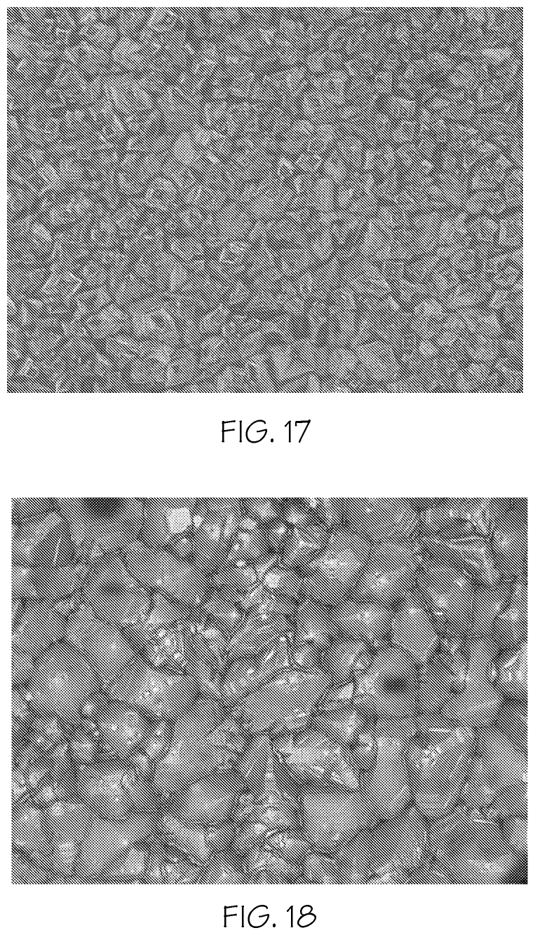

Referring now to FIGS. 17 and 18, treating Glass Article GA with Etchant EA resulted in Example Textured Article TA having sufficient coverage and micro-uniformity of the resulting polyhedral surface features. As shown in FIGS. 17 and 18, Example Textured Article TA included triangular and quadrangular pyramids.

As shown in Table 3 above, Example Textured Article TA had a surface feature size of 115 μm, a surface feature height of 13 μm, a triangular pyramid facet angle of 15.0°, a quadrangular pyramid facet angle of 15.0°, and a surface roughness of 4.0 μm.

### Example 2—Example Textured Article TB (Etchant EB and Glass Article GB)

To obtain Etchant EB, 616 g blended powder including 97.5 wt % NH₄HF₂ and 2.5 wt % SiO₂ gel was obtained by hand mill. 1212 g pre-mixed solvent including 26.0 wt % HCl, 71.0 wt % H₂O, and 3.0 wt % C₃HgO₃ was obtained and stirred adequately. The mixture of powder and solvent was performed at 24° C. The etchant was cooled to 12° C.

Glass Article GB was subjected to the same treatment as Glass Article GA in Example 1 prior to etching.

Glass Article GB was submerged and cycled in Etchant EB for a period of 240 s and at a cycling speed of 20 cm/s. The temperature of Etchant EB was 12° C.

Etched Glass Article GB was subjected to the same treatment as Glass Article GA in Example 1 after etching.

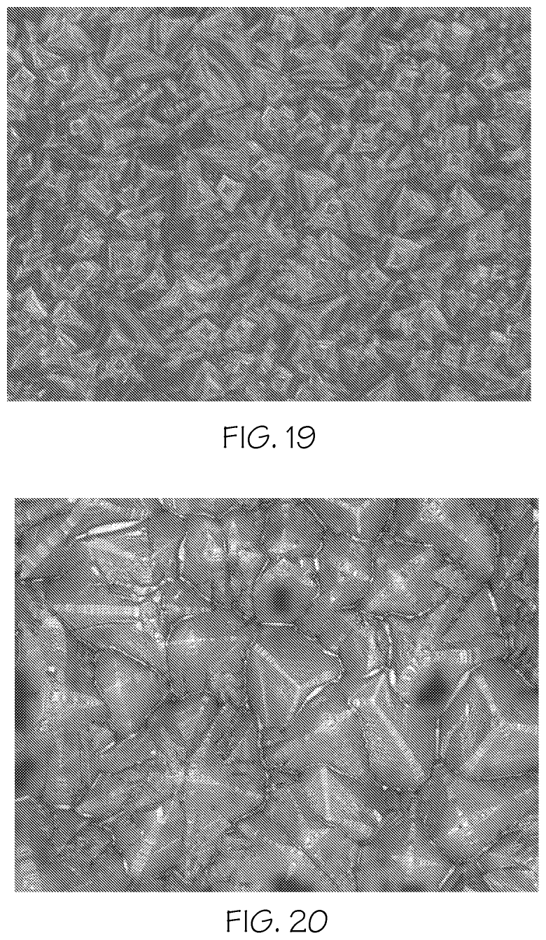

Referring now to FIGS. 19 and 20, treating Glass Article GB with Etchant EB resulted in Example Textured Article TB having sufficient coverage and micro-uniformity of the resulting polyhedral surface features. As shown in FIGS. 19 and 20, Example Textured Article TB included triangular and quadrangular pyramids.

As shown in Table 3 above, Example Textured Article TB had a surface feature size of 140 μm, a surface feature height of 30 μm, a triangular pyramid facet angle of 18.5°, a quadrangular pyramid facet angle of 19.0°, and a surface roughness of 6.0 μm.

### Coated Textured Glass Articles

Layers of Example Coating CA were sequentially disposed on top of one another on Example Textured Article TA to form Example Coated Textured Article CTA. The structure of Coated Textured Glass Article CTA, including the layers of Coating CA, the relative refractive index of each layer, and the relative thickness of each layer, is shown in Table 4.

Both SiO₂ and Si₃N₄ layers were made by reactive sputtering in an AJA-Industries Sputter Deposition Tool. SiO₂ was deposited by DC reactive sputtering from an Si target with an ion assist. Si₃N₄ was deposited by DC reactive sputtering combined with RF superimposed DC sputtering with ion assist. The targets were 3″ diameter Silicon and 3″ diameter Nitrogen. The reactive gasses were nitrogen and oxygen, and the “working” (or inert) gas was Argon. The power supplied to the Silicon was radio frequency (RG) at 13.56 Mhz. The power supplied to the Nitrogen was DC.

TABLE 4
STRUCTURE OF EXAMPLE COATED
TEXTURED ARTICLECTA

| | | Refractive Index | |
|---|---|---|---|
| Layer | Material | at 500 nm | Thickness (nm) |
| Ambient | Air | 1.000 | — |
| CoatingCA | | | |
| Layers | | | |
| 1 | SiO₂ | 1.463 | 15.00 |
| 2 | Si₃N₄ | 2.014 | 2000.00 |
| 3 | SiO₂ | 1.463 | 8.67 |
| 4 | Si₃N₄ | 2.014 | 43.72 |
| 5 | SiO₂ | 1.463 | 30.18 |
| 6 | Si₃N₄ | 2.014 | 25.79 |
| 7 | SiO₂ | 1.463 | 53.51 |
| 8 | Si₃N₄ | 2.014 | 9.94 |
| 9 | SiO₂ | 1.463 | 25.00 |
| Substrate | Textured Article | 1.508 | 6000.00 |
| | TA | | |

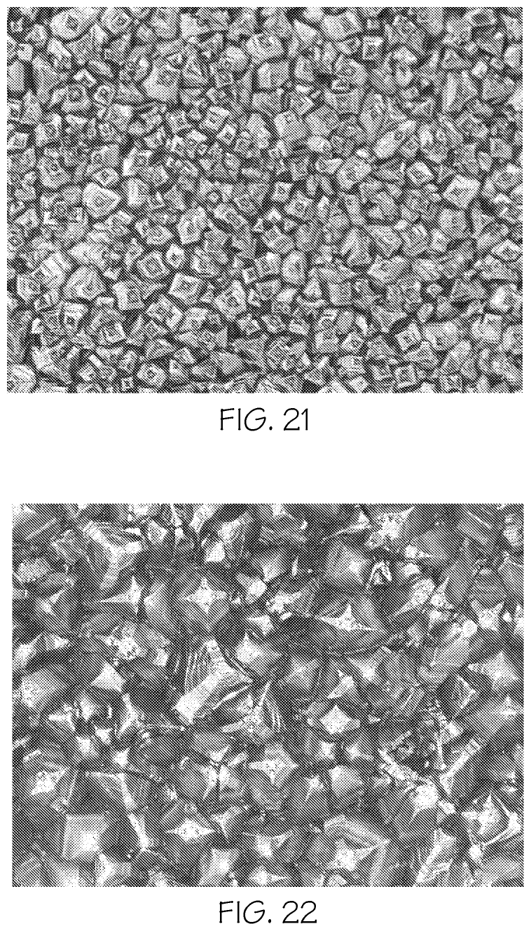

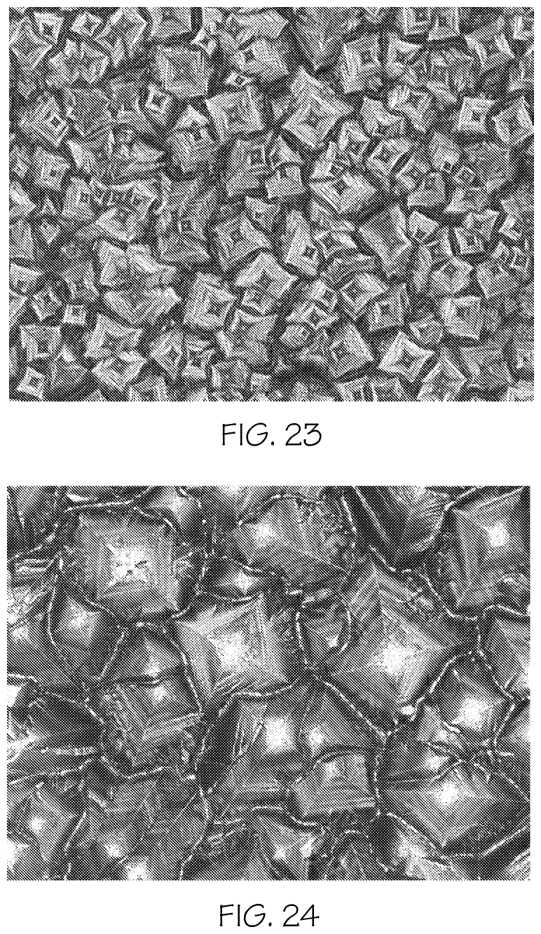

Referring now to FIGS. 21 and 22, layers of Example Coating CB were sequentially disposed on one another on Example Textured Article TA to form Example Coated Textured Article CTB. The structure of Coated Textured Glass Article CTB, including the layers of Coating CB, the relative refractive index of each layer, and the relative thickness of each layer, is shown in Table 5.

The layers of Coating CB were formed by reactive sputtering as described with respect to Coating CA.

TABLE 5
STRUCTURE OF EXAMPLE COATED
TEXTURED ARTICLECTB

| | | Refractive Index | |
|---|---|---|---|
| Layer | Material | at 500 nm | Thickness (nm) |
| Ambient | Air | 1.000 | — |
| Coating CB | | | |
| Layers | | | |
| 1 | SiO₂ | 1.476 | 113.13 |
| 2 | Si₃N₄ | 2.014 | 2000.00 |
| 3 | SiO₂ | 1.476 | 116.56 |
| 4 | Si₃N₄ | 2.014 | 167.10 |
| 5 | SiO₂ | 1.476 | 104.04 |
| 6 | Si₃N₄ | 2.013 | 71.57 |
| 7 | SiO₂ | 1.476 | 106.13 |
| 8 | Si₃N₄ | 2.014 | 78.95 |
| 9 | SiO₂ | 1.476 | 25.00 |
| Substrate | Textured Article | 1.508 | 6000.00 |
| | TA | | |

Referring now to FIGS. 23 and 24, layers of Example Coating CB were sequentially disposed on one another on Example Textured Article TB to form Example Coated Textured Article CTC. The structure of Coated Textured Article CTC, including the layers of Coating CB, the relative refractive index of each layer, and the relative thickness of each layer, is shown in Table 6.

TABLE 6
STRUCTURE OF EXAMPLE COATED
TEXTURED ARTICLECTC

| | | Refractive Index | |
|---|---|---|---|
| Layer | Material | at 500 nm | Thickness (nm) |
| Ambient | Air | 1.000 | — |
| Coating CB | | | |
| Layers | | | |
| 1 | SiO₂ | 1.476 | 113.13 |
| 2 | Si₃N₄ | 2.014 | 2000.00 |
| 3 | SiO₂ | 1.476 | 116.56 |
| 4 | Si₃N₄ | 2.014 | 167.10 |
| 5 | SiO₂ | 1.476 | 104.04 |
| 6 | Si₃N₄ | 2.013 | 71.57 |
| 7 | SiO₂ | 1.476 | 106.13 |
| 8 | Si₃N₄ | 2.014 | 78.95 |
| 9 | SiO₂ | 1.476 | 25.00 |
| Substrate | Textured Article | 1.508 | 6000.00 |
| | TB | | |

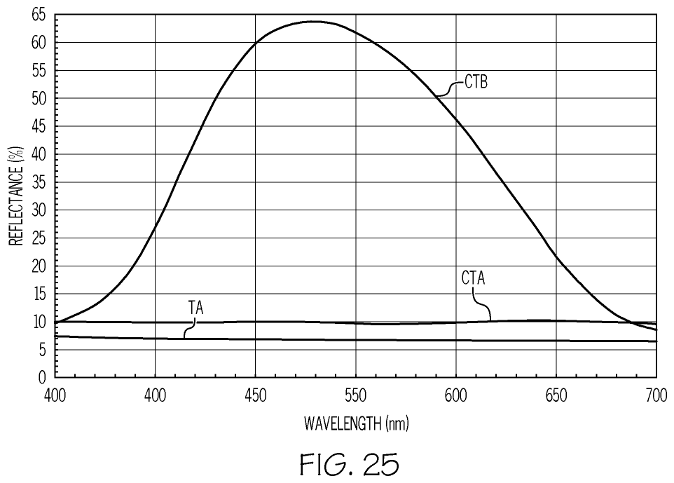

Referring now to FIG. 25, Example Textured Article TA and Example Coated Textured Article CTA had a single side average photopic light reflectance of about 7% and about 10%, respectively, over a wavelength range from 400 nm to 700 nm. As exemplified by FIG. 25, the coated textured glass articles described herein may have a higher reflectance as compared to a textured glass article without a coating.

Also shown in FIG. 25, Example Coated Textured Article CTB had a substantially higher reflectance across the visible wavelength range (i.e., from 400 nm to 700 nm), with a peak reflectance of about 535 nm, resulting in a green visual appearance at points along the article. As exemplified by FIG. 25, the color properties of the coated textured articles described herein may be tuned to provide a desired color appearance.

Referring now to Table 7, the specular component included (SCI) values of L*, a*, b* and the single side average phototopic light reflectance for Example Textured Article TA, Example Coated Textured Article CTA, and Example Coated Textured Article CTB are shown.

TABLE 7

| | Example | Example Coated | Example Coated |
|---|---|---|---|
| | Textured | Textured | Textured |
| | Article TA | Article CTA | Article CTB |
| L* | 31.25 | 37.50 | 78.64 |
| a* | −0.24 | 0.09 | −28.30 |
| b* | −1.11 | −0.29 | 29.10 |
| Reflectance (%) | 6.80 | 9.89 | 36.82 |

Example Coated Textured Article CTA had a higher brightness value L* and reflectance than Example Textured Article TA, while maintaining a neutral color and visual appearance, as indicated by the a* and b* values. Example Coated Textured Article CTB had a higher brightness value L* and reflectance than Example Textured Article TA, while providing a green visual appearance, as indicated by the a* and b* values. As exemplified by Table 7, the coated textured articles described herein may be tuned to provide a desired reflectance, brightness, and color appearance.

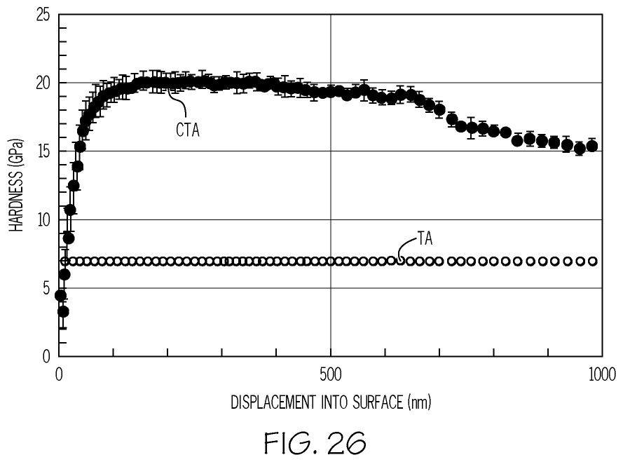

Referring now to FIG. 26, Example Textured Article TA and Example Coated Textured Article CTA had a maximum hardness of 7 GPa and 20 GPa, respectively. As exemplified by FIG. 26, the coating of the coated textured glass articles described herein imparts a desired hardness.

It will be apparent to those skilled in the art that various modifications and variations may be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

Embodiment 1: A coated textured glass article comprising: a glass body comprising a first surface; a glass body comprising a first surface; a plurality of polyhedral surface features extending from the first surface, each of the plurality of polyhedral surface features comprising a base on the first surface and a plurality of facets extending from the base and converging toward one another; and a coating disposed on the first surface of the body and the plurality of polyhedral surface features, the coating comprising a multilayer interference stack.

Embodiment 2. The article of Embodiment 1, wherein the plurality of polyhedral surface features comprises a surface feature size greater than or equal to 50 μm and less than or equal to 300 μm.

Embodiment 3. The article of Embodiment 1 or Embodiment 2 wherein the plurality of polyhedral surface features comprises a surface feature height greater than or equal to 10 μm and less than or equal to 40 μm.

Embodiment 4. The article of any one of Embodiment 1 to Embodiment 3, wherein the plurality of polyhedral surface features comprises triangular pyramids, quadrangular pyramids, or a combination thereof.

Embodiment 5. The article of any one of Embodiment 1 to Embodiment 4, wherein the plurality of polyhedral surface features comprises a facet angle greater than or equal to 100 and less than or equal to 25°.

Embodiment 6. The article of any one of Embodiment 1 to Embodiment 5, wherein the plurality of polyhedral surface features comprises a surface roughness greater than or equal to 2 μm and less than or equal to 7 μm.

Embodiment 7. The article of any one of Embodiment 1 to Embodiment 6, wherein the multilayer interference stack comprises a plurality of layers, wherein the plurality of layers comprises at least one low refractive index layer and at least one high refractive index layer.

Embodiment 8. The article of Embodiment 7, wherein the multilayer interference stack comprises at least one period, each period comprising one of the at least one low refractive index layers and one of the at least one high refractive index layers.

Embodiment 9. The article of Embodiment 8, wherein the multilayer interference stack comprises from 1 to 20 periods.

Embodiment 10. The article of any one Embodiment 7 to Embodiment 9, wherein the at least one low refractive index layer comprises SiO₂, Al₂O₃, GeO₂, SiO, AlOₓN_{y}, SiOₓNᵤ, SiAlₓO_{y}, SiᵤAlᵥOₓN_{y}, MgO, MgAl₂O₄, MgF₂, BaF₂, CaF₂, DyF₃, YbF₃, CeF₃, or a combination thereof, wherein subscripts “u,” “x,” and “y” are from 0 to 1.

Embodiment 11. The article of any one of Embodiment 7 to Embodiment 10, wherein the at least one high refractive index layer comprises SiᵤAlᵥOₓN_{y}, Ya₂O₅, Nb₂O₅, AlN, Si₃N₄, AlOₓN_{y}, SiOₓN_{y}, HfO₂, TiO₂, ZrO₂, Y₂O₃, Al₂O₃, MoO₃, diamond-like carbon, or a combination thereof, wherein subscripts “u,” “x,” and “y” are from 0 to 1.

Embodiment 12. The article of any one of Embodiment 7 to Embodiment 11, wherein the at least one low refractive index layer comprises a thickness greater than or equal to 2 nm and less than or equal to 200 nm.

Embodiment 13. The article of any one of Embodiment 7 to Embodiment 12, wherein the at least one high refractive index layer comprises a thickness greater than or equal to 5 nm and less than or equal to 5000 nm.

Embodiment 14. The article of any one of Embodiment 1 to Embodiment 13, wherein the multilayer interference stack comprises an outer surface opposite the first surface of the body, and wherein the article comprises a hardness greater than or equal to 10 GPa, as measured at the outer surface by a Berkovich Indenter Hardness Test along an indentation depth of 100 nm to 500 nm.

Embodiment 15. The article of any one of Embodiment 1 to Embodiment 14, wherein the multilayer interference stack comprises an outer surface opposite the first surface of the body, and wherein the article comprises a single side average photopic light reflectance greater than or equal to 4%, as measured at the outer surface at an incident illumination angle of 6°, referenced to normal incidence, over a wavelength range from 400 nm to 700 nm.

Embodiment 16. The article of Embodiment 15, wherein the single side average photopic light reflectance of the article is greater than or equal to 7%, as measured at the outer surface at an incident illumination angle of 6°, referenced to normal incidence, over a wavelength range from 400 nm to 700 nm.

Embodiment 17. The article of Embodiment 16, wherein the single side average photopic light reflectance of the article is greater than or equal to 10%, as measured at the outer surface at an incident illumination angle of 6°, referenced to normal incidence, over a wavelength range from 400 nm to 700 nm.

Embodiment 18. The article of Embodiment 17, wherein the single side average photopic light reflectance of the article is greater than or equal to 20%, as measured at the outer surface at an incident illumination angle of 6°, referenced to normal incidence, over a wavelength range from 400 nm to 700 nm.

Embodiment 19. The article of any one of Embodiment 1 to Embodiment 18, wherein the multilayer interference stack comprises an outer surface opposite the first surface of the body, and wherein the article comprises a peak single side light reflectance greater than or equal to 25%, as measured at the outer surface at an incident illumination angle of 6°, referenced to normal incidence, over a wavelength range from 400 nm to 700 nm.

Embodiment 20. The article of Embodiment 19, wherein the peak single side light reflectance of the article is greater than or equal to 40%, as measured at the outer surface at an incident illumination angle of 6°, referenced to normal incidence, over a wavelength range from 400 nm to 700 nm.

Embodiment 21. The article of Embodiment 20, wherein the peak single side light reflectance of the article is greater than or equal to 50%, as measured at the outer surface at an incident illumination angle of 6°, referenced to normal incidence, over a wavelength range from 400 nm to 700 nm.

Embodiment 22. The article of any one of Embodiment 1 to Embodiment 21, wherein the article comprises a peak single side light reflectance from 520 nm to 560 nm, as measured at the outer surface at an incident illumination angle of 6°, referenced to normal incidence, over a wavelength range from 400 nm to 700 nm.

Embodiment 23. The article of any one of Embodiment 1 to Embodiment 22, wherein the article comprises an article reflectance color coordinate L* greater than or equal to 20 and less than or equal to 90, as measured under D65 illumination and a 100 standard observer angle.

Embodiment 24. The article of any one of Embodiment 1 to Embodiment 23, wherein the article comprises at least one of article reflectance color coordinates a* and b* greater than or equal to −30 and less than or equal to 30, as measured under D65 illumination and a 100 standard observer angle.

Embodiment 25. The article of any one of Embodiment 1 to Embodiment 24, wherein: the article exhibits an angular color shift greater than or equal to 5, as measured at an incident illumination angle greater than or equal to 20 degrees, referenced to normal incidence, under D65 illumination; and the angular color shift is calculated using the equation ((a*₂−a*₁)²+(b*₂−b*₁)²), with a*1, and b*₁ representing the coordinates of the article when viewed at normal incidence and a*₂, and b*₂ representing the coordinates of the article when viewed at the incident illumination angle.

Embodiment 26. The article of any one of Embodiment 1 to Embodiment 25, wherein the article exhibits a reference point color shift greater than or equal to 2, as measured at a normal incidence under D65 illumination; and the reference point color shift is calculated using the equation (a*²+b*²).

Embodiment 27. The article of any one of Embodiment 1 to Embodiment 26, wherein the glass body comprises aluminosilicate glass.

Embodiment 28. The article of any one of Embodiment 1 to Embodiment 27, wherein the glass body comprises a glass-ceramic body.

Embodiment 29. A coated textured glass article comprising: a glass body comprising a first surface; a plurality of polyhedral surface features extending from the first surface; and a coating disposed on the first surface of the body and the plurality of polyhedral surface features, the coating comprising a multilayer interference stack, the multilayer interference stack comprising an outer surface opposite the first surface of the body, wherein: the article comprises a single side average photopic light reflectance greater than or equal to 4%, as measured at the outer surface at an incident illumination angle of 6°, referenced to normal incidence, over a wavelength range from 400 nm to 700 nm.

Embodiment 30. The article of Embodiment 29, wherein the article comprises a hardness greater than or equal to 10 GPa, as measured on the outer surface by a Berkovich Indenter Hardness Test along an indentation depth of 100 nm to 500 nm.

Embodiment 31. The article of Embodiment 29 or Embodiment 30, wherein the single side average photopic light reflectance of the article is greater than or equal to 7%, as measured at the outer surface at an incident illumination angle of 6°, referenced to normal incidence, over a wavelength range from 400 nm to 700 nm.

Embodiment 32. The article of Embodiment 31, wherein the single side average photopic light reflectance of the article is greater than or equal to 10%, as measured at the outer surface at an incident illumination angle of 6°, referenced to normal incidence, over a wavelength range from 400 nm to 700 nm.

Embodiment 33. The article of Embodiment 32, wherein the single side average photopic light reflectance of the article is greater than or equal to 20%, as measured at the outer surface at an incident illumination angle of 6°, referenced to normal incidence, over a wavelength range from 400 nm to 700 nm.

Embodiment 34. The article of any one of Embodiment 29 to Embodiment 33, wherein the article comprises a peak single side light reflectance greater than or equal to 25%, as measured at the outer surface at an incident illumination angle of 6°, referenced to normal incidence, over a wavelength range from 400 nm to 700 nm.

Embodiment 35. The article of Embodiment 34, wherein the peak single side light reflectance of the article is greater than or equal to 40%, as measured at the outer surface at an incident illumination angle of 6°, referenced to normal incidence, over a wavelength range from 400 nm to 700 nm.

Embodiment 36. The article of Embodiment 35, wherein the peak single side light reflectance of the article is greater than or equal to 50%, as measured at the outer surface at an incident illumination angle of 6°, referenced to normal incidence, over a wavelength range from 400 nm to 700 nm.

Embodiment 37. The article of any one of Embodiment 29 to Embodiment 36, wherein the article comprises a peak single side light reflectance from 520 nm to 560 nm, as measured at the outer surface at an incident illumination angle of 6°, referenced to normal incidence, over a wavelength range from 400 nm to 700 nm.

Embodiment 38. The article of any one of Embodiment 29 to Embodiment 37, wherein the article comprises an article reflectance color coordinate L* greater than or equal to 20 and less than or equal to 90, as measured under D65 illumination and a 100 standard observer angle.

Embodiment 39. The article of any one of Embodiment 29 to Embodiment 38, wherein the article comprises at least one of article reflectance color coordinates a* and b* greater than or equal to −30 and less than or equal to 30, as measured under D65 illumination and a 100 standard observer angle.

Embodiment 40. The article of any one of Embodiment 29 to Embodiment 39, wherein: the article exhibits an angular color shift greater than or equal to 5, as measured at an incident illumination angle greater than or equal to 20 degrees, referenced to normal incidence, under D65 illumination; and the angular color shift is calculated using the equation ((a*₂−a*₁)²+(b*₂−b*₁)²), with a*₁, and b*₁ representing the coordinates of the article when viewed at normal incidence and a*₂, and b*₂ representing the coordinates of the article when viewed at the incident illumination angle.

Embodiment 41. The article of any one of Embodiment 29 to Embodiment 40, wherein the article exhibits a reference point color shift greater than or equal to 2, as measured at a normal incidence under D65 illumination; and the reference point color shift is calculated using the equation (a*²+b*²).

Embodiment 42. The article of any one of Embodiment 29 to Embodiment 41, wherein each of the plurality of polyhedral surface features comprise a base on the first surface and a plurality of facets extending from the base and converging toward one another.

Embodiment 43. The article of any one of Embodiment 29 to Embodiment 42, wherein the plurality of polyhedral surface features comprise: a surface feature size greater than or equal to 50 μm and less than or equal to 300 μm; a surface feature height greater than or equal to 10 μm and less than or equal to 40 μm; a facet angle greater than or equal to 100 and less than or equal to 25°; and a surface roughness greater than or equal to 2 μm and less than or equal to 7 μm.

Embodiment 44. The article of any one of Embodiment 29 to Embodiment 43, wherein the plurality of polyhedral surface features comprises triangular pyramids, quadrangular pyramids, or a combination thereof.

Embodiment 45. The article of any one of Embodiment 29 to Embodiment 44, wherein the multilayer interference stack comprises a plurality of layers, wherein the plurality of layers comprises at least one low refractive index layer and at least one high refractive index layer.

Embodiment 46. The article of Embodiment 45, wherein the at least one low refractive index layer comprises SiO₂ and the at least one high refractive index layer comprise Si₃N₄.

Embodiment 47. The article of Embodiment 45 or Embodiment 46, wherein: the at least one low refractive index layer comprises a thickness greater than or equal to 2 nm and less than or equal to 200 nm; and the at least on high refractive index layer comprises a thickness greater than or equal to 5 nm and less than or equal to 5000 nm.

Embodiment 48. The article of any one of Embodiment 29 to Embodiment 47, wherein the glass body comprises aluminosilicate glass.

Embodiment 49. The article of any one of Embodiment 29 to Embodiment 48, wherein the glass body comprises a glass-ceramic body.

Embodiment 50. A coated textured glass article comprises: a glass body comprising a first surface; a plurality of polyhedral surface features extending from the first surface, each of the plurality of polyhedral surface features comprising a base on the first surface and a plurality of facets extending from the base and converging toward one another, the plurality of polyhedral surface features comprising a surface feature size greater than or equal to 50 μm and less than or equal to 300 μm and a surface feature height greater than or equal to 10 μm and less than or equal to 40 μm; and a coating disposed on the first surface of the body and the plurality of polyhedral surface features, the coating comprising a multilayer interference stack, the multilayer interference stack comprising an outer surface opposite the first surface of the body, wherein: the article comprises a single side average photopic light reflectance greater than or equal to 4%, as measured at the outer surface at an incident illumination angle of 6°, referenced to normal incidence, over a wavelength range from 400 nm to 700 nm.

Embodiment 51. The article of Embodiment 50, wherein the plurality of polyhedral surface features comprises a facet angle greater than or equal to 10° and less than or equal to 250 and a surface roughness greater than or equal to 2 μm and less than or equal to 7 μm.

Embodiment 52. The article of Embodiment 50 or Embodiment 51, wherein the plurality of polyhedral surface features comprises triangular pyramids, quadrangular pyramids, or a combination thereof.

Embodiment 53. The article any one of Embodiment 50 to Embodiment 52, wherein the multilayer interference stack comprises a plurality of layers, the plurality of layers comprising at least one low refractive index layer and at least one high refractive index layer.

Embodiment 54. The article of Embodiment 53, wherein the at least one low refractive index layer comprises SiO₂ and the at least one high refractive index layer comprises Si₃N₄.

Embodiment 55. The article of Embodiment 53 to Embodiment 54, wherein the at least one low refractive index layer comprises a thickness greater than or equal to 2 nm and less than or equal to 200 nm and the at least one high refractive index layer comprises a thickness greater than or equal to 5 nm and less than or equal to 5000 nm.

Embodiment 56. The article of any one of Embodiment 50 to Embodiment 55, wherein the article comprises a hardness greater than or equal to 10 GPa, as measured on the outer surface by a Berkovich Indenter Hardness Test along an indentation depth of 100 nm to 500 nm.

Embodiment 57. The article of any one of Embodiment 50 to Embodiment 56, wherein the single side average photopic light reflectance of the article is greater than or equal to 7%, as measured at the outer surface at an incident illumination angle of 6°, referenced to normal incidence, over a wavelength range from 400 nm to 700 nm.

Embodiment 58. The article of Embodiment 57, wherein the single side average photopic light reflectance of the article at the outer surface is greater than or equal to 10%, as measured at the outer surface at an incident illumination angle of 6°, referenced to normal incidence, over a wavelength range from 400 nm to 700 nm.

Embodiment 59. The article of Embodiment 58, wherein the single side average photopic light reflectance of the article is greater than or equal to 20%, as measured at the outer surface at an incident illumination angle of 6°, referenced to normal incidence, over a wavelength range from 400 nm to 700 nm.

Embodiment 60. The article of any one of Embodiment 50 to Embodiment 59, wherein the article comprises a peak single side light reflectance greater than or equal to 25%, as measured at the outer surface at an incident illumination angle of 6°, referenced to normal incidence, over a wavelength range from 400 nm to 700 nm.

Embodiment 61. The article of Embodiment 60, wherein the peak single side light reflectance of the article is greater than or equal to 40%, as measured at the outer surface at an incident illumination angle of 6°, referenced to normal incidence, over a wavelength range from 400 nm to 700 nm.

Embodiment 62. The article of Embodiment 61, wherein the peak single side light reflectance of the article is greater than or equal to 50%, as measured at the outer surface at an incident illumination angle of 6°, referenced to normal incidence, over a wavelength range from 400 nm to 700 nm.

Embodiment 63. The article of any one of Embodiment 50 to Embodiment 62, wherein the article wherein the article comprises a peak single side light reflectance from 520 nm to 560 nm, as measured at the outer surface at an incident illumination angle of 6°, referenced to normal incidence, over a wavelength range from 400 nm to 700 nm.

Embodiment 64. The article of any one of Embodiment 50 to Embodiment 63, wherein the article comprises an article reflectance color coordinate L* greater than or equal to 20 and less than or equal to 90, as measured under D65 illumination and a 100 standard observer angle.

Embodiment 65. The article of any one of Embodiment 50 to Embodiment 64, wherein the article comprises at least one of article reflectance color coordinates a* and b* greater than or equal to −30 and less than or equal to 30, as measured under D65 illumination and a 100 standard observer angle.

Embodiment 66. The article of any one of Embodiment 50 to Embodiment 65, wherein: the article exhibits an angular color shift greater than or equal to 5, as measured at an incident illumination angle greater than or equal to 20 degrees, referenced to normal incidence, under D65 illumination; and the angular color shift is calculated using the equation ((a*₂−a*₁)²+(b*₂−b*₁)²), with a*₁, and b*₁ representing the coordinates of the article when viewed at normal incidence and a*₂, and b*₂ representing the coordinates of the article when viewed at the incident illumination angle.

Embodiment 67. The article of any one of Embodiment 50 to Embodiment 66, wherein the article exhibits a reference point color shift greater than or equal to 2, as measured at a normal incidence under D65 illumination; and the reference point color shift is calculated using the equation (a*²+b*²).

Embodiment 68. A consumer electronic device comprises: a housing having a front surface, a back surface, and side surfaces; and electrical components provided at least partially within the housing, the electrical components including at least a controller, a memory, and a display, the display being provided at or adjacent the front surface of the housing; wherein the back surface of the housing includes the coated textured glass article of any one of Embodiment 1 to Embodiment 28.

Embodiment 69. A consumer electronic device comprises: a housing having a front surface, a back surface, and side surfaces; and electrical components provided at least partially within the housing, the electrical components including at least a controller, a memory, and a display, the display being provided at or adjacent the front surface of the housing; wherein the back surface of the housing includes the coated textured glass article of any one of Embodiment 29 to Embodiment 49.

Embodiment 70. A consumer electronic device comprises: a housing having a front surface, a back surface, and side surfaces; and electrical components provided at least partially within the housing, the electrical components including at least a controller, a memory, and a display, the display being provided at or adjacent the front surface of the housing; wherein the back surface of the housing includes the coated textured glass article of any one of Embodiment 50 to Embodiment 67.

1. A coated textured glass article comprising:
a glass body comprising a first surface;
a plurality of polyhedral surface features extending from the first surface, each of the plurality of polyhedral surface features comprising a base on the first surface and a plurality of facets extending from the base and converging toward one another; and
a coating disposed on the first surface of the body and the plurality of polyhedral surface features, the coating comprising a multilayer interference stack.

2. The article of claim 1, wherein the plurality of polyhedral surface features comprises a surface feature size greater than or equal to 50 μm and less than or equal to 300 μm.

3. The article of claim 1, wherein the plurality of polyhedral surface features comprises a surface feature height greater than or equal to 10 μm and less than or equal to 40 μm.

4. The article of claim 1, wherein the plurality of polyhedral surface features comprises triangular pyramids, quadrangular pyramids, or a combination thereof.

5. The article of claim 1, wherein the plurality of polyhedral surface features comprises a facet angle greater than or equal to 100 and less than or equal to 25°.

6. The article of claim 1, wherein the plurality of polyhedral surface features comprises a surface roughness greater than or equal to 2 μm and less than or equal to 7 μm.

7. The article of claim 1, wherein the multilayer interference stack comprises a plurality of layers, wherein the plurality of layers comprises at least one low refractive index layer and at least one high refractive index layer.

8. The article of claim 7, wherein the multilayer interference stack comprises at least one period, each period comprising one of the at least one low refractive index layers and one of the at least one high refractive index layers.

9. The article of claim 8, wherein the multilayer interference stack comprises from 1 to 20 periods.

10. The article of claim 7, wherein the at least one low refractive index layer comprises SiO₂, Al₂O₃, GeO₂, SiO, AlOₓN_{y}, SiOₓNᵤ, SiAlₓO_{y}, SiᵤAlᵥOₓN_{y}, MgO, MgAl₂O₄, MgF₂, BaF₂, CaF₂, DyF₃, YbF₃, CeF₃, or a combination thereof, wherein subscripts “u,” “x,” and “y” are from 0 to 1.

11. The article of claim 7, wherein the at least one high refractive index layer comprises Siᵤ AlᵥOₓN_{y}, Ya₂O₅, Nb₂O₅, AlN, Si₃N₄, AlOₓN_{y}, SiOₓN_{y}, HfO₂, TiO₂, ZrO₂, Y₂O₃, Al₂O₃, MoO₃, diamond-like carbon, or a combination thereof, wherein subscripts “u,” “x,” and “y” are from 0 to 1.

12. The article of claim 7, wherein the at least one low refractive index layer comprises a thickness greater than or equal to 2 nm and less than or equal to 200 nm.

13. The article of claim 7, wherein the at least one high refractive index layer comprises a thickness greater than or equal to 5 nm and less than or equal to 5000 nm.

14. The article of claim 1, wherein the multilayer interference stack comprises an outer surface opposite the first surface of the body, and wherein the article comprises a hardness greater than or equal to 10 GPa, as measured at the outer surface by a Berkovich Indenter Hardness Test along an indentation depth of 100 nm to 500 nm.

15. The article of claim 1, wherein the multilayer interference stack comprises an outer surface opposite the first surface of the body, and wherein the article comprises a single side average photopic light reflectance greater than or equal to 4%, as measured at the outer surface at an incident illumination angle of 6°, referenced to normal incidence, over a wavelength range from 400 nm to 700 nm.

16. The article of claim 15, wherein the single side average photopic light reflectance of the article is greater than or equal to 7%, as measured at the outer surface at an incident illumination angle of 6°, referenced to normal incidence, over a wavelength range from 400 nm to 700 nm.

17. The article of claim 16, wherein the single side average photopic light reflectance of the article is greater than or equal to 10%, as measured at the outer surface at an incident illumination angle of 6°, referenced to normal incidence, over a wavelength range from 400 nm to 700 nm.

18. The article of claim 17, wherein the single side average photopic light reflectance of the article is greater than or equal to 20%, as measured at the outer surface at an incident illumination angle of 6°, referenced to normal incidence, over a wavelength range from 400 nm to 700 nm.

19. The article of claim 1, wherein the multilayer interference stack comprises an outer surface opposite the first surface of the body, and wherein the article comprises a peak single side light reflectance greater than or equal to 25%, as measured at the outer surface at an incident illumination angle of 6°, referenced to normal incidence, over a wavelength range from 400 nm to 700 nm.

20. The article of claim 19, wherein the peak single side light reflectance of the article is greater than or equal to 40%, as measured at the outer surface at an incident illumination angle of 6°, referenced to normal incidence, over a wavelength range from 400 nm to 700 nm.

21. The article of claim 20, wherein the peak single side light reflectance of the article is greater than or equal to 50%, as measured at the outer surface at an incident illumination angle of 6°, referenced to normal incidence, over a wavelength range from 400 nm to 700 nm.

22. The article of claim 1, wherein the article comprises a peak single side light reflectance from 520 nm to 560 nm, as measured at the outer surface at an incident illumination angle of 6°, referenced to normal incidence, over a wavelength range from 400 nm to 700 nm.

23. The article of claim 1, wherein the article comprises an article reflectance color coordinate L* greater than or equal to 20 and less than or equal to 90, as measured under D65 illumination and a 100 standard observer angle.

24. The article of claim 1, wherein the article comprises at least one of article reflectance color coordinates a* and b* greater than or equal to −30 and less than or equal to 30, as measured under D65 illumination and a 100 standard observer angle.

25. The article of claim 1, wherein:
the article exhibits an angular color shift greater than or equal to 5, as measured at an incident illumination angle greater than or equal to 20 degrees, referenced to normal incidence, under D65 illumination; and
the angular color shift is calculated using the equation √((a*₂−a*₁)²+(b*₂−b*₁)²), with a*₁, and b*₁ representing the coordinates of the article when viewed at normal incidence and a*₂, and b*₂ representing the coordinates of the article when viewed at the incident illumination angle.

26. The article of claim 1, wherein the article exhibits a reference point color shift greater than or equal to 2, as measured at a normal incidence under D65 illumination; and
the reference point color shift is calculated using the equation √(a*²+b*²).

27. The article of claim 1, wherein the glass body comprises aluminosilicate glass.

28. The article of claim 1, wherein the glass body comprises a glass-ceramic body.

29. A coated textured glass article comprising:
a glass body comprising a first surface;
a plurality of polyhedral surface features extending from the first surface; and
a coating disposed on the first surface of the body and the plurality of polyhedral surface features, the coating comprising a multilayer interference stack, the multilayer interference stack comprising an outer surface opposite the first surface of the body, wherein:
the article comprises a single side average photopic light reflectance greater than or equal to 4%, as measured at the outer surface at an incident illumination angle of 6°, referenced to normal incidence, over a wavelength range from 400 nm to 700 nm.

30.-49. (canceled)

50. A coated textured glass article comprising:
a glass body comprising a first surface;
a plurality of polyhedral surface features extending from the first surface, each of the plurality of polyhedral surface features comprising a base on the first surface and a plurality of facets extending from the base and converging toward one another, the plurality of polyhedral surface features comprising a surface feature size greater than or equal to 50 μm and less than or equal to 300 μm and a surface feature height greater than or equal to 10 μm and less than or equal to 40 μm; and
a coating disposed on the first surface of the body and the plurality of polyhedral surface features, the coating comprising a multilayer interference stack, the multilayer interference stack comprising an outer surface opposite the first surface of the body, wherein:
the article comprises a single side average photopic light reflectance greater than or equal to 4%, as measured at the outer surface at an incident illumination angle of 6°, referenced to normal incidence, over a wavelength range from 400 nm to 700 nm.

51.-67. (canceled)

68. A consumer electronic device, comprising:
a housing having a front surface, a back surface, and side surfaces; and
electrical components provided at least partially within the housing, the electrical components including at least a controller, a memory, and a display, the display being provided at or adjacent the front surface of the housing;
wherein the back surface of the housing includes the coated textured glass article of claim 1.

69. A consumer electronic device, comprising:
a housing having a front surface, a back surface, and side surfaces; and
electrical components provided at least partially within the housing, the electrical components including at least a controller, a memory, and a display, the display being provided at or adjacent the front surface of the housing;
wherein the back surface of the housing includes the coated textured glass article of claim 29.

70. A consumer electronic device, comprising:
a housing having a front surface, a back surface, and side surfaces; and
electrical components provided at least partially within the housing, the electrical components including at least a controller, a memory, and a display, the display being provided at or adjacent the front surface of the housing;
wherein the back surface of the housing includes the coated textured glass article of claim 50.
